(19) United States
(12) Patent Application Publication
(10) Pub. No.: US 2022/0171908 A1
(43) Pub. Date: Jun. 2, 2022

(54) SUPPORT SYSTEM AND SUPPORT METHOD SUPPORTING SYSTEM CONSTRUCTION

(71) Applicant: Hitachi, Ltd., Tokyo (JP)

(72) Inventors: Masaki SAWAHATA, Tokyo (JP); Akinori YOKOI, Tokyo (JP); Daiki YAMAMOTO, Tokyo (JP)

(21) Appl. No.: 17/483,911

(22) Filed: Sep. 24, 2021

(30) Foreign Application Priority Data
Nov. 27, 2020 (JP) 2020-196690

(51) Int. Cl. G06F 30/27

(52) U.S. Cl. CPC G06F 30/27

(57) ABSTRACT

There is an on-site process as at least part of an OT-side process. The on-site process includes one or more tasks that start and finish for each of one or more targets. A pseudo model that simulates such an on-site process is prepared. A support system executes the pseudo model, and executes an IT-side process, based on pseudo execution data that is data obtained by executing the pseudo model.

### CROSS-REFERENCE TO PRIOR APPLICATION

This application relates to and claims the benefit of priority from Japanese Patent Application number 2020-196690, filed on Nov. 27, 2020 the entire disclosure of which is incorporated herein by reference.

### BACKGROUND

In general, the present invention relates to a technology for supporting system construction and, for example, relates to a novel technology for supporting system construction that requires data as a result of an OT-side process that is a process on an OT (Operation Technology) side, for an IT-side process that is a process on an IT (Information Technology) side.

In this specification, “system” constructed by “system construction” may be a system as hardware, a system as software, a system as a combination of hardware and software, or a system as a service provided based on hardware, software or a combination thereof (for example, a cloud computing service). For example, “system” may include one or more apparatuses. The “apparatus” may be a system itself, or a component of a system. Each of the one or more apparatuses may be a physical apparatus or a virtual apparatus.

In this specification, “construction” of “system construction” may include assembling for forming, as a system, one or more developed and designed apparatuses, or may include at least one of development and design instead of or in addition to assembling.

A technology related to system construction may be, for example, a technology disclosed in PLT1 and PLT2. PLT1 discloses a technology related to manufacturing line design. PLT2 discloses a technology related to development of a device emulated in a virtual machine environment.
PLT1: Japanese Patent Laid-Open No. 2003-44115
PLT2: Japanese Patent Laid-Open No. 2006-18814

### SUMMARY

As to system construction, a system construction that requires data as a result of an OT-side process for an IT-side process has been known. This type of system construction is applied to construction of a system related to an environment where one or more tasks that start and finish for one or more targets are executed on site. “Object” may be a tangible object or an intangible object. An example of “task” may be an operation or a step. An “object” is taken in into a task, then is subject to the task, and an “object” is then taken out of the task. “Target” may be a concept accommodating the entire “object” taking in into or taking out of the task, or “object” itself.

An example of “system” to be constructed is at least one of the followings.
A system visualizing a production activity. In this system, an example of “target” may be a product. An example of “object” may be a material, a semifinished product (intermediate product), a finished product, etc. An example of “task” may be a step (for example, material cutting out, pressing, or assembling).
A system visualizing management. In this system, an example of “target” may be KPI (Key Performance Indicator). An example of “object” may be information. An example of “task” may be an operation, such as of information analysis, and project planning.
A system entering and dispatching from a warehouse. In this system, an example of “target” may be an availability situation in a warehouse. An example of “object” may be merchandise or a container containing merchandise. An example of “task” may be a step of conveying merchandise or a container containing merchandise.
A system performing conveyance. In this system, an example of “target” may be an operation of conveyance. An example of “object” may be merchandise or a container containing merchandise. An example of “task” may be a step of carrying merchandise or a container containing merchandise to a picking station.

In such system construction, the OT-side process requires trial and error to obtain data to be handed off to the IT-side process. Specifically, for example, one or more people actually go to an actual site. All the tasks are repeatedly executed experimentally, and setting of elements (e.g., sensors) related to the tasks are appropriately adjusted.

For the OT-side process, an original task (actual task) on the site can be required to be stopped. The stop time period can sometimes increase. As a result, the original task on the site is delayed, and the schedule becomes tight or is delayed. Accordingly, at least one of the followings is concerned. As a result, there is a possibility of increase in cost and of opportunity loss.
The start of the IT-side process can be delayed, which prolongs the time period until completion of the system construction.
The load on at least one (typically both) of a customer (an example of the introduction destination) of a system constructed by the system construction, and a supplier (an example of the introduction source) is heavy. Accordingly, the cost (e.g., operation load) until completion of the system construction increases.

There is an on-site process as at least part of the OT-side process. The on-site process includes one or more tasks that respectively start and finish for each of one or more targets. A pseudo model that is a model simulating such an on-site process is prepared. A support system executes the pseudo model, and executes an IT-side process, based on pseudo execution data that is data obtained by execution of the pseudo model.

According to the present invention, at least one of the followings is expected.
The IT-side process is started without waiting for the OT-side process, and prevents the time period until completion of the system construction from being prolonged.
The OT-side process becomes efficient based on a result at the middle or after completion of the IT-side process, and the cost until completion of system construction is reduced.

### BRIEF DESCRIPTION OF THE DRAWINGS

FIG. 1 shows a comparative example of an embodiment;

FIG. 2 shows a concept of the embodiment;

FIG. 3 shows an overview of a support system according to the embodiment;

FIG. 4 shows a configuration example of the support system;

FIG. 5 shows examples of information and functions that a management server has;

FIG. 6 schematically shows examples of the configuration and execution of a pseudo model;

FIG. 7A shows a first example of the configuration of the pseudo model;

FIG. 7B shows a second example of the configuration of the pseudo model;

FIG. 7C shows a third example of the configuration of the pseudo model;

FIG. 8 shows a configuration example of a control function table;

FIG. 9 shows a configuration example of a macro step table;

FIG. 10 shows a configuration example of a step table;

FIG. 11 shows a configuration example of a preprocess table;

FIG. 12 shows a configuration example of a rule table;

FIG. 13 shows a configuration example of a resource table;

FIG. 14 shows a configuration example of scenario construction data;

FIG. 15 shows a configuration example of scenario data;

FIG. 16 shows a configuration example of a macro step configuration table;

FIG. 17 schematically shows an example of instantiation of a scenario;

FIG. 18 shows a configuration example of scenario instance data;

FIG. 19 shows a configuration example of actual execution data;

FIG. 20 shows a configuration example of pseudo execution data;

FIG. 21 shows an example of a flow of processes including a preprocess, a scheduling process, and an instantiation process;

FIG. 22 shows an example of a flow of S2106 (instantiation process) of FIG. 21;

FIG. 23 shows an example of a flow of a main process;

FIG. 24 shows an example of a flow of S2303 (arrangement execution) of FIG. 23;

FIG. 25 shows an example of a flow of S2305 (step execution) of FIG. 23;

FIG. 26 shows an example of a flow of a process of checking the pseudo execution data;

FIG. 27 shows an example of a flow of a process of generating the pseudo execution data;

FIG. 28 schematically shows part of a specific example of the process of generating the pseudo execution data;

FIG. 29 schematically shows part of a specific example of the process of generating the pseudo execution data; and

FIG. 30 schematically shows part of a specific example of the process of generating the pseudo execution data.

### DESCRIPTION OF EMBODIMENTS

In the following description, “interface device” may be one or more interface devices. The one or more interface devices may be at least one of the followings.
One or more I/O (Input/Output) interface devices. The I/O (Input/Output) interface device is an interface device for at least one of an I/O device and a remote display computer. The I/O interface device for the display computer may be a communication interface device. At least one I/O device may be a user interface device, for example, any of an input device such as a keyboard and a pointing device, and an output device such as a display device.
One or more communication interface devices. The one or more communication interface devices may be one or more identical types of communication interface devices (e.g., one or more NICs (Network Interface Cards)), or two or more different types of communication interface devices (e.g., a NIC and an HBA (Host Bus Adapter)).

In the following description, “memory” is one or more memory devices, which are an example of one or more storage devices, and typically is a main storage device. At least one memory device in the memory may be a volatile memory device or a non-volatile memory device.

In the following description, “persistent storage device” is one or more persistent storage devices, which are an example of one or more storage devices. Typically, the persistent storage device may be a non-volatile storage device (e.g., an auxiliary storage device). Specifically, this device may be an HDD (Hard Disk Drive), SSD (Solid State Drive), NVME (Non-Volatile Memory Express) drive, or SCM (Storage Class Memory).

In the following description, “storage device” may be at least a memory between the memory and the persistent storage device.

In the following description, “processor” may be one or more processor devices. Typically, at least one processor device may be a microprocessor device, such as a CPU (Central Processing Unit). Alternatively, this device may be another type of processor device, such as a GPU (Graphics Processing Unit). At least one processor device may be a single-core one or a multi-core one. At least one processor device may be a processor core. At least one processor device may be a processor device in a broad sense, such as a circuit that is an aggregate of gate arrays (e.g., an FPGA (Field-Programmable Gate Array), a CPLD (Complex Programmable Logic Device) or an ASIC (Application Specific Integrated Circuit)) with a hardware description language for performing part of or the entire process.

In the following description, a function is sometimes described using a representation of “yyy unit (-or)”. The function may be achieved by one or more computer programs being executed by a processor, by one or more hardware circuits (e.g., FPGAs or ASICs), or by a combination thereof. In the case where the program is achieved by being executed by the processor, a defined process is performed appropriately using the storage device and/or the interface device or the like. Accordingly, the function may be regarded as at least part of the processor. A process described with the function being adopted as a subject may be a process performed by the processor or a device that includes the processor. The program may be installed from a program source. The program source may be, for example, a recording medium (e.g., a non-transitory recording medium) that a program distributing computer or a computer can read. The description of each function is only an example. Multiple functions may be integrated into a single function. A single function may be divided into multiple functions.

In the following description, the process is sometimes described with “program” being adopted as a subject. The process described with the program being adopted as the subject may be a process performed by the processor or a device that includes the processor. Two or more programs may be achieved as a single program. A single program may be achieved as two or more programs.

In the following description, information according to which an output is obtained with respect to an input is described with a representation such as of “xxx table”. The information may be a table having any structure, or a learning model typified by a neural network, a genetic algorithm, or a random forest through which an output is caused with respect to an input. Consequently, “xxx table” can be called “xxx information”. In the following description, the configuration of each table is only an example. A single table may be divided into two or more tables. All or some of two or more tables may be a single table.

The following description adopts a system visualizing a production activity (a system providing what is called a manufacturing dashboard) as a system constructed by system construction. The target of visualization may be at least one of 4M (huMan, Machine, Material, and Method). Accordingly, in the following description, the following may be adopted.
An example of “target” is “product”. An example of “object” is “material” or “product”. The “product” may be any of an item (e.g., material) before entering the manufacturing system, an item in the middle of the manufacturing system (what is called “semifinished product”) and a finished product that can be shipped after all the corresponding steps in the manufacturing system. The “product” may be a semifinished product or a finished product.
Examples of “task” are “arrangement” and “step”.
The resource related to each of one or more tasks is at least one of a resource as an object itself (e.g., Material) and a resource for an object (e.g., Machine, and huMan).

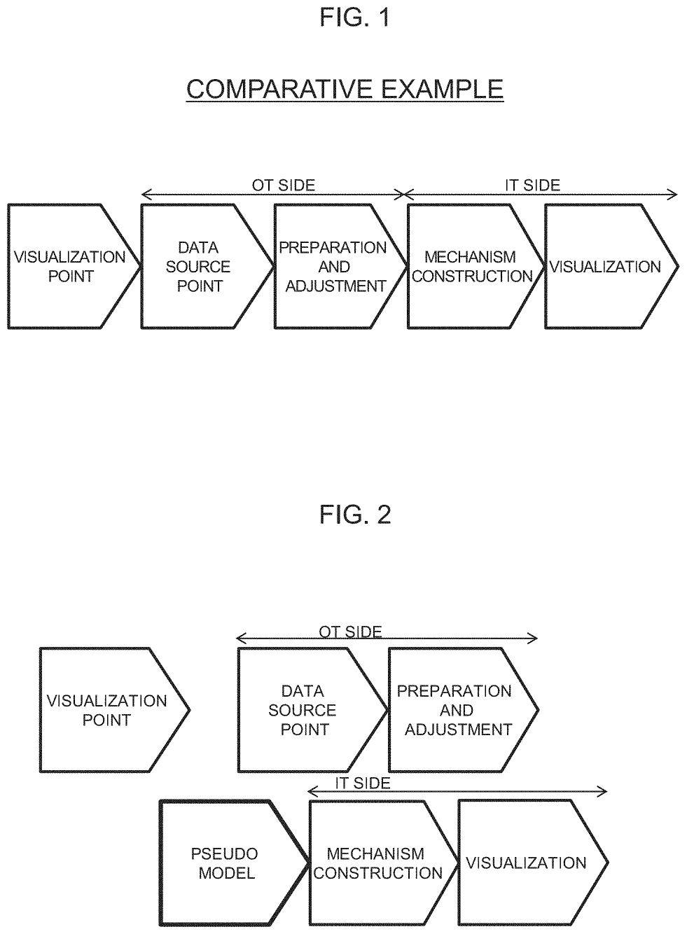

FIG. 1 shows a comparative example of an embodiment.

An example of visualizing the production activity is indication of a chart that associates the relationship between data representing undertaking or completion of each step (Method) with data representing the states of a facility (Machine), a person (huMan) and a material (Material), and represents the relationship between the time and at least one of 4M. Accordingly, at least one of the followings is achieved. Consequently, at least one of the lead time, the amount of production, the availability rate, and the defect rate is expected to be optimized. The productivity can therefore be expected to be improved.

(1) Reduction in productivity is recognized.
(2) The cause is identified.
(3) By grasping the impact degree, an improvement activity having a high effect is preferentially executed.
(4) The improvement effect is verified in a short span.
(5) The bottleneck is resolved.

Obtainment of data on the undertaking time and the completion time of each step, and data representing the states of the facility, people and material, and association of such data require a long time period and are partially difficult.

The processes for visualization include an OT-side process and an IT-side process. Trial and error are repeated on a micro level (for example, in units of OT-side process and IT-side process), and on a macro level (for example, over all the processes for visualization).

Specifically, for example, first, a visualization point (what is visualized and how) is determined. Next, in the OT-side process, one or more people actually go to a site, a data source point is determined, and a mechanism for obtaining data is constructed. The construction of this mechanism allows data to be obtained. Accordingly, the IT-side process (for example, (1) construction of a processing function in conformity with the characteristics of actual data, and meaning of the data, and (2) achievement of visualization) can be started.

The OT-side process includes an operation that requires the cost and time period of procurement, installation and adjustment of facilities (e.g., PLCs (Programmable Logic Controllers), sensors, and NT devices). If the mechanism for obtaining data is not constructed temporarily after such an OT-side process, no IT-side process can be started, and the time period until completion of constructing the visualization system is prolonged accordingly. Furthermore, the OT-side process requires trial and error, which increases the cost and time period required for the OT-side process.

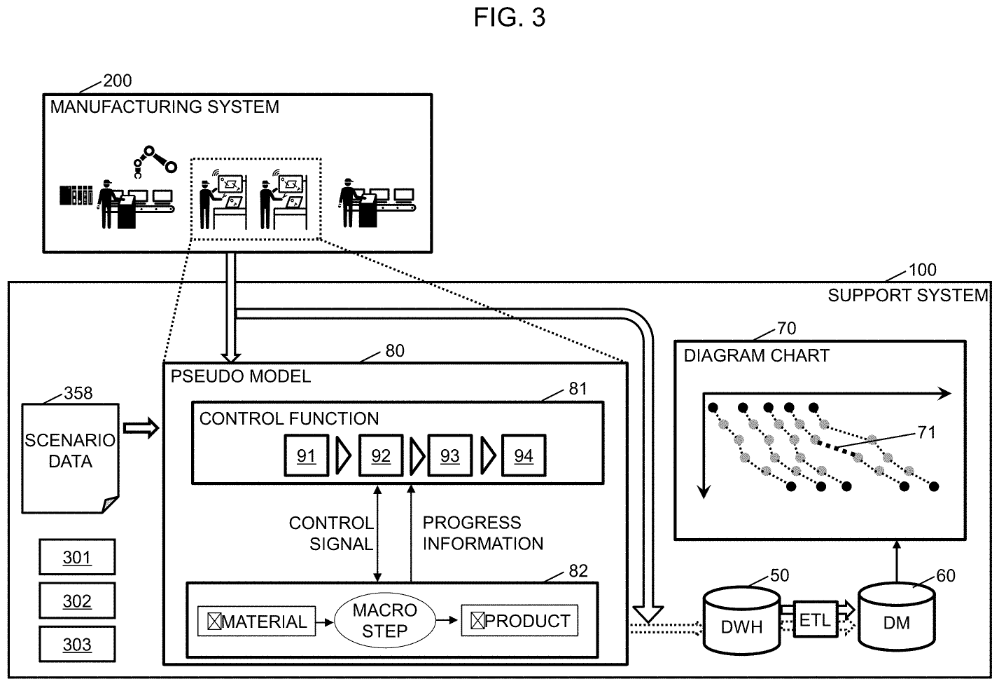

FIG. 2 shows a concept of the embodiment.

There is an on-site process as at least part of the OT-side process. “On-site process” includes one or more tasks that respectively start and finish for one or more targets. In this embodiment, the on-site process includes determination of the data source point, and adjustment of the facility. For each target, the task may start at an opportunity of an object taken in into or taken out of the task (or at an explicit (for example, a start by an operation instruction) or implicit (for example, a start at a determined time) opportunity of a start instruction). For each target, the task may finish at an opportunity of an object taken in into or taken out of the task (or at an explicit (for example, a finish by an operation instruction) or implicit (for example, a finish at a determined time) opportunity of a finish instruction).

A pseudo model of an on-site process is prepared. By the pseudo model is executed, data is obtained in a simulated manner. Based on the obtained data (pseudo execution data), the IT-side process can be started. That is, without waiting for completion of the OT-side process, the IT-side process can be started. As indicated in the example in FIG. 2, the OT-side process and the IT-side process are executed in parallel (any of the OT-side process and the IT-side process may be executed first). Thus, while the OT-side process and the IT-side process are serially arranged according to a comparative example, these processes may be arranged in parallel according to this embodiment. Consequently, the time period until completion of system construction can be expected to be prevented from being prolonged. A result at the middle or after completion of the IT-side process is fed back to the OT-side process, thereby allowing the OT-side process to be efficient (for example, the operation can be shorten or omitted). Consequently, the cost until completion of system construction can be expected to be reduced.

Instead of execution in parallel as described above, the IT-side process is executed first. Based on an execution result of the IT-side process, the OT-side process may be started. Accordingly, the OT-side process can become efficient. Consequently, the cost until completion of system construction can be reduced. By making the OT-side process efficient, the time period until completion of system construction can be prevented from being prolonged as a whole.

According to this embodiment, more specifically, for example, at least one of the followings can be expected.
Without dependence on progress of the OT-side process, a manufacturing dashboard can be constructed as a result of visualization. Accordingly, early hypothesis verification
(for example, verification of selection of the visualization point and the data source point), early customer feedback obtainment through providing the manufacturing dashboard for a customer (an example of the introduction destination), and repetition of efficient trial and error can be expected.
In some cases, part of the on-site process may be part of the pseudo model without being realized. Accordingly, a part having relatively low importance (for example, a part having low value for the customer) can be avoided from being realized, and more efficient system construction can be expected.
Without going to the site (or significant reduction in the number of times of going to the site), the visualization system of the production activity (manufacturing site) can be delivered remotely. Accordingly, even in a situation incapable of going to the site (for example, under a pandemic), any of operations of the supplier and customer can be continued.

FIG. 3 shows an overview of a support system according to the embodiment.

A support system 100 is a system that supports system construction of the visualization system of a manufacturing system 200. The system construction includes the OT-side process and the IT-side process. The IT-side process requires data as a result of the OT-side process.

A pseudo model 80 that simulates the on-site process as at least part of the OT-side process is prepared for the support system 100. The pseudo model 80 includes one or more macro modules 82, and a control function 81 that controls the one or more macro modules 82. The macro module 82 represents taking-in into a macro step, such as for one or more materials and the like, the macro step, and one or more products taking-out from the macro step. Multiple macro steps may be sequentially executed. Alternatively, some of macro steps among the macro steps may be simultaneously executed. The control function 81 may be a device that controls the multiple macro steps, and a function simulating a control device in the manufacturing system 200.

The support system 100 includes an OT executor 301, an IT executor 302, and an UI (User Interface) unit 303. The UI unit 303 accepts an input of information from a user, and displays information.

The OT executor 301 executes the pseudo model 80. Scenario data 358 is input to execute the pseudo model 80. The scenario data 358 represents a scenario of the pseudo model 80. In this embodiment, the scenario may be called “constraint”. The representation of the scenario may be an event-based representation of 4M (for example, irregular-event-oriented scenario representation). The scenario may include the necessity of synchronization between macro steps.

Execution of the pseudo model 80 includes a preprocess 91, a scheduling process 92, an instantiation process 93, and a main process 94. The preprocess 91 includes determination of whether the scenario contradicts or not. The scheduling process 92 includes determination of the start time and the completion time of each step for each product. The instantiation process 93 includes determination of an instance of the scenario. The main process 94 includes simulated execution of each step. In the main process 94, for example, the control function 81 controls execution, stopping, restart or the like of the macro step through a control signal, and detects the progress of the macro step. The operation of such a control function 81 may be defined in the pseudo model 80.

The IT executor 302 executes an IT-side process, based on pseudo execution data that is data obtained by execution of the pseudo model 80. In this embodiment, as indicated by broken line frame arrows in FIG. 3, the IT-side process includes: storing the pseudo execution data in a DWH (Data Ware House) 50; storing data, in a DM (Data Mart) 60, data extracted from the DWH 50 through ETL (Extract/Transform/Load); generating a manufacturing dashboard on the basis of the data in the DM 60; and displaying the manufacturing dashboard through the UI unit 303. A diagram chart 70 exemplified in FIG. 3 is an example of the manufacturing dashboard. In the diagram chart 70, the abscissa axis is an axis corresponding to the time, and the ordinate axis is an axis corresponding to the arrangement and step. That is, the diagram chart 70 is a chart showing the start times and completion times of the arrangement and the step on a product-by-product basis in a comprehensive view. In accordance with the example shown in FIG. 3, in the diagram chart 70, a line segment 71 corresponding to delay or the time and arrangement or step where the delay occurs is highlighted. Note that as for each broken line in the diagram chart 70, points at the opposite ends may be points in accordance with given values based on an actual execution result and the like in an on-site process, and points intervening between the opposite points may be points in accordance with values estimated based on the pseudo execution data.

For example, at least one of the followings may be adopted.
When there is actual execution data that is data as an actual execution result of the OT-side process (for example, an in-process or past execution result), as indicated by solid frame arrows in FIG. 3, at least part of the actual execution data may be used to execute the pseudo model 80, stored in the DWH 50, or extracted by ETL and stored in the DM 60.
The control function 81 is not necessarily included in the pseudo model 80. For example, a function equivalent to the control function 81 may be included in the OT executor 301. However, the form where the pseudo model 80 includes the control function 81, and the OT executor 301 executes the process specified in the control function 81 can be expected to execute, in a simulated manner, the process more suitable to the pseudo model 80 (more suitable to the on-site process simulated by the pseudo model 80).
Instead of input of the scenario data 358 from the outside of the pseudo model 80, the scenario data 358 may be preliminarily included in the pseudo model 80. By preparing the scenario data 358 separately from the pseudo model 80, diversity of executions of the same pseudo model 80 (for example, occurrence of multiple irregular events) is easily achieved. For example, only by changing the parameters in the scenario data 358, the execution content of the pseudo model 80 is expected to be changed.
At least one of the DWH 50, ETL and DM 60 is not necessarily adopted. For example, in the IT-side process, the diagram chart 70 may be generated from the pseudo execution data itself, and be displayed.

Hereinafter, this embodiment is described in detail.

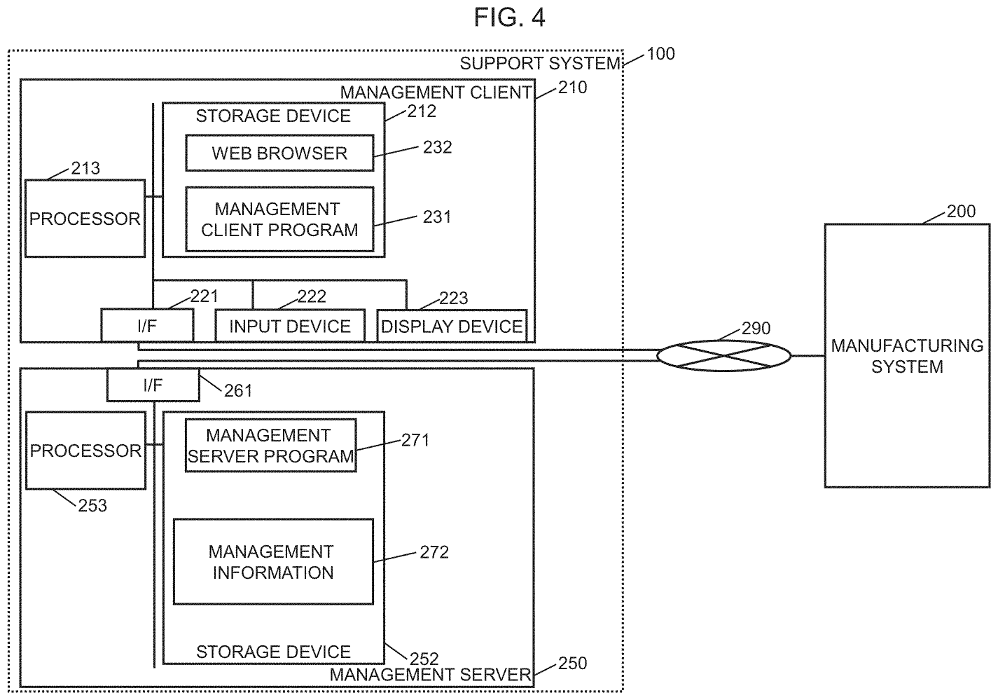

FIG. 4 shows a configuration example of the support system 100.

The support system 100 includes a management server 250, and one or more management clients 210 coupled to the management server 250. The management clients 210 and the manufacturing system 200 are coupled to the management server 250 via a communication network (for example, a LAN (Local Area Network) WAN (Wide Area Network) or the Internet) 290.

Multiple facilities (apparatuses) for multiple steps, multiple sensors that periodically measure measurement items about the respective steps, and a server that stores multiple measured values periodically obtained by the sensors and transmits these measured values to the management server 250 can be installed, for example, in the OT-side process, in the manufacturing system 200. Information (e.g., raw data, such as manufacturing dynamic data, facility data, and quality measured data) can be periodically or irregularly transmitted from the manufacturing system 200 to the management server 250, and stored in this management server 250. The information includes, for example, a production ID, a start time and a completion time of each step, with respect to each product. The manufacturing system 200 may be any type of manufacturing system, for example, any of a job shop manufacturing system, a cellular manufacturing system, and a line manufacturing system.

The management client 210 includes an I/F (interface device) 211, an input device 222, a display device 223, a storage device 212, and a processor 213 coupled to these components.

The I/F 211 may be a communication interface device coupled to a communication network 290. The input device 222 may be a pointing device and a keyboard. The display device 223 may be a device that includes a physical screen on which information displayed. A touch screen that integrally includes the input device 222 and the display device 223 may be adopted (for example, the management client 210 may be a smart device, such as a smart phone).

The storage device 212 stores a computer program executed by the processor 213, and information to be used by the processor 213. Specifically, for example, the storage device 212 stores a management client program 231, and a web browser 232. The management client program 231 communicates with the management server 250, and displays an UI, such as a manufacturing dashboard, via the web browser 232.

The management server 250 includes an I/F 261, a storage device 252, and a processor 253 coupled to these components.

The I/F 261 may be a communication interface device coupled to a communication network 290.

The storage device 252 stores a computer program executed by the processor 253, and information to be used by the processor 253. Specifically, for example, the storage device 252 stores a management server program 271, and management information 272. The management server program 271 communicates with the management client program 231. The management information 272 may include: information about the pseudo model 80; information about achievements, such as the start time and completion time of each step on a product-by-product basis; the raw data described above; and various thresholds.

A linkage process of the management server program 271, the management client program 231 and the web browser 232 achieves an UI display, such as a manufacturing dashboard.

The DWH 50 and the DM 60 exemplified in FIG. 3 may be provided based on the storage device 252 of the management server 250. The support system 100 may be a system that includes one or more physical computers, or a system (e.g., a cloud computing system) achieved on a physical computing resource group (e.g., a cloud foundation). “Display(ing)” of display information by the support system 100 may be displaying of display information on a display device included in the computer, or transmission of display information by the computer to the display computer (in the latter case, the display information is displayed by the display computer).

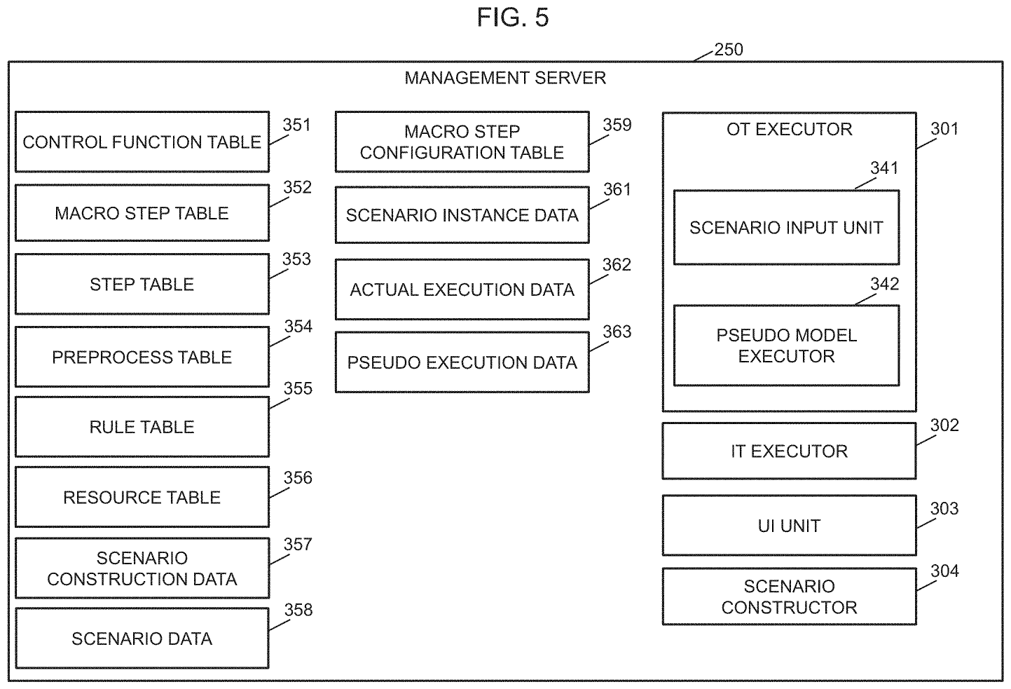

FIG. 5 shows examples of information and functions that the management server 250 has.

Examples of components included in the management information 272 exemplified in FIG. 4 include a control function table 351, a macro step table 352, a step table 353, a preprocess table 354, a rule table 355, a resource table 356, scenario construction data 357, scenario data 358, a macro step configuration table 359, scenario instance data 361, actual execution data 362, and pseudo execution data 363.

Examples of functions achieved by the processor 253 executing the management server program 271 exemplified in FIG. 4 include the OT executor 301 that executes the pseudo model 80 on the basis of the scenario data 358, the IT executor 302 that executes the IT-side process, the UI unit 303 that accepts an input of information from the user and displays information for the user, and the scenario constructor 304 that constructs the scenario data 358. The OT executor 301 includes a scenario input unit 341 that receives the scenario data 358 constructed by the scenario constructor 304, and a pseudo model executor 342 that executes the pseudo model 80 on the basis of the scenario data 358 input through the scenario input unit 341.

The pseudo model 80 is based on the control function table 351, the macro step table 352, the step table 353, the preprocess table 354, the rule table 355, and the resource table 356. The pseudo model 80 may include numerical values of the start time and completion time of the step and the states of resources (e.g., facilities, people or materials), a model (e.g., a mathematical expression) that receives the numerical values as input, or information representing the relationship between the on-site process simulated by the pseudo model 80 and processes before and after the process.

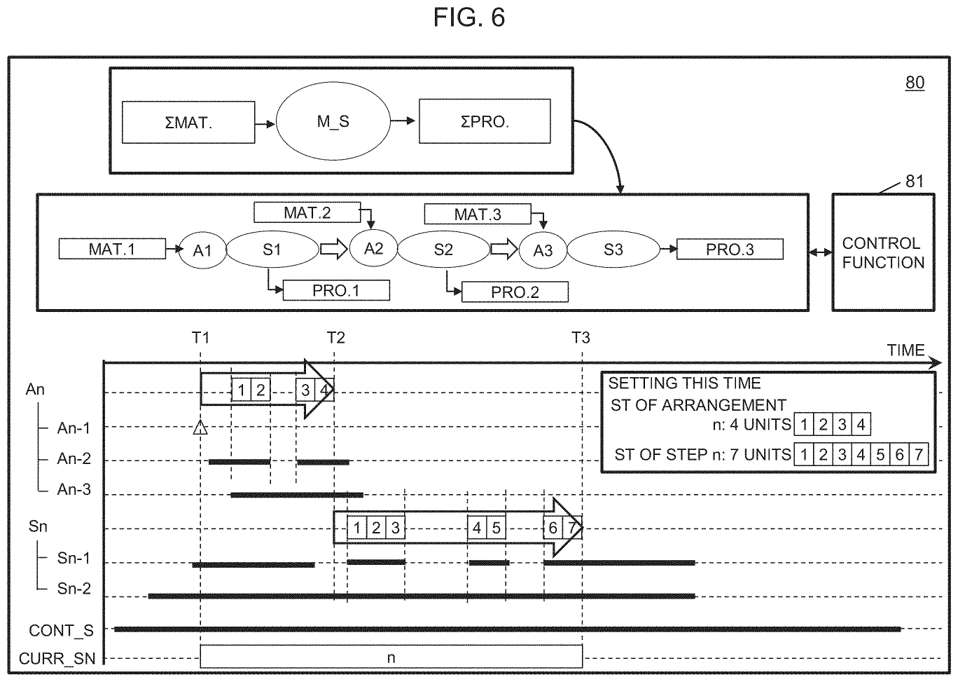

FIG. 6 schematically shows examples of the configuration and execution of the pseudo model 80.

First, terms described in FIG. 6 are as follows.
“MAT.” means a material.
“PRO.” means a product.
“Ai” (natural numbers of i=1, 2, . . . , n) means an arrangement i. The arrangement i is an arrangement for the step i (the step having the step number i).
“Ai-N” (N is a natural number) means the resources related to the arrangement i or the situation thereof. For example, An-1 represents the material. An-2 represents the operation availability of a wheeled platform. An-3 represents the operation availability of an arrangement operator. For each of An-2 and An-3, thick lines means a state where the operation is available.
“Si” (i is a natural number in some cases) means the step i.
“Si-M” (M is an natural number) means the resources related to the step i or the situation thereof. For example, Sn-1 represents the operation availability of the facility. Sn-2 represents the operation availability of a step operator. For each of Sn-1 and Sn-2, thick lines mean a state where the operation is available.
“CONT_S” means a control signal output from the control function 81. The thick line means the ON state of CONT_S.
“CURR_SN” means a signal representing the current step number. The number of current step numbers that are present at the same time may be one or more. That is, in the macro step there may be one step at the same time, or multiple tasks at the same time.

For example, the macro step is made up of one or more arrangement and step pairs, and corresponds to a model of one production activity. An example of “one production activity” described here is to input one or more materials, apply the arrangement and step to the one or more materials, and output a product as a result of the step. The “arrangement and step pair” is a serial pair of the arrangement i and the step i. The macro step starts when the required materials arrive and the required resources (e.g., people and facilities) are available, and stops and restarts in accordance with the operation availabilities of the resources. Note that one of the step i and the arrangement i may be absent (NOP (No OPeration)).

The control function 81 may control a single or multiple macro steps in cooperation (for example, control stopping and restarting of the operation by CONT_S), and control the operation availabilities of the resources (for example, people and facilities).

The arrangement i is an activity that is required to achieve the operable state of the step i and includes conveyance of the material from the step before the step i, and is part of the production activity. The time period TA required for the arrangement i may be represented as an arrangement standard time period ST_{A}+Δ, for example.

The step i is a predetermined activity that starts upon completion of the arrangement i, and is part of the production activity. The time period T_{S} required for the step i may be represented as a step standard time period ST_{N}+Δ, for example.

The arrangement i and the step i may be modeled together, or modeled separately.

According to the example shown in FIG. 6, the modeling is as follows, for example.
At the time (triangle mark) T1 when the material (An-1) arrives, the arrangement n starts. CURB SN represents “n”. When CONT_S is in the ON state, the wheeled platform (An-2) is in an operable state and the arrangement operator (An-3) is in an operable state, the arrangement n is executed with four unit time periods being adopted as the arrangement standard time period, and the arrangement n is finished at a time T2. Since stopping and restarting occur, the time period (the time period from T1 to T2) required for the arrangement n is longer than the arrangement standard time period.
When the arrangement n is finished, the step n is started. The start time of the step n is the completion time T2 of the step n. When CONT_S is in the ON state, the arrangement (Sn-1) is in an operable state and the step operator (Sn-2) is in an operable state, the step n is executed with seven unit time periods being adopted as the step standard time period, and the step n is finished at a time T3. Since stopping and restarting occur, the time period (from T2 to T3) required for the step n is longer than the step standard time period.

As the configuration of the pseudo model 80, any of multiple types of configurations may be adopted.

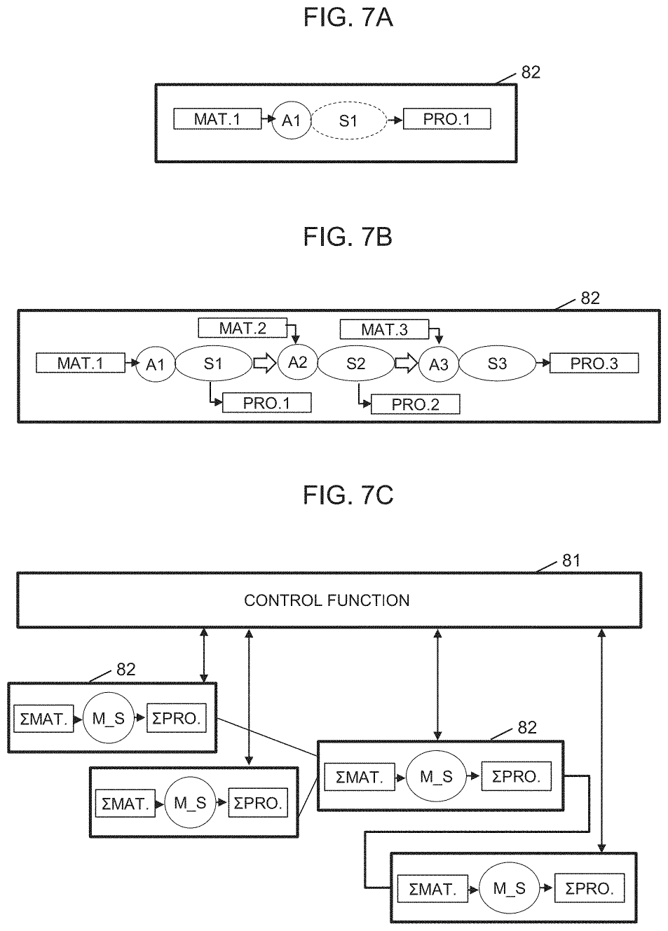

For example, as exemplified in FIG. 7A, the number of macro modules 82 included in the pseudo model 80 may be one. The macro step represented by the macro module 82 may be a single arrangement and step pair. A step 1 that is an example of one of the arrangement and the step of this pair may be NOP (NOP (No OPeration)).

For example, as exemplified in FIG. 7B, the number of macro modules 82 included in the pseudo model 80 may be one. The macro steps represented by the macro module 82 may be multiple arrangement and step pairs. For each arrangement and step pair, the input of the material and the output of the product may be defined.

For example, as exemplified in FIG. 7C, the number of macro modules 82 included in the pseudo model 80 may be plural. The execution order of the macro steps represented by the macro modules 82 may be defined. Each of the macro steps includes one or more steps where the execution order is specified. As described above, the pseudo model may be a model of a graph structure (for example, DAG (Directed Acyclic Graph)) whose nodes are multiple macro steps. Each macro step may be an integrated group of steps (one or more steps). The edge represents the order between the macro steps.

Accordingly, the configuration of the manufacturing site can be appropriately represented. For example, if a certain macro step is focused, the relationship with the parent of the macro step or a child macro step can be easily grasped. Note that the execution order of two or more macro steps to be simultaneously executed may be the same. The pseudo model 80 may include the control function 81 that controls execution of multiple macro steps represented by multiple macro modules 82. Note that the control function 81 may be included in the pseudo model 80 even in a case where the number of macro modules 82 included in the pseudo model 80 is one.

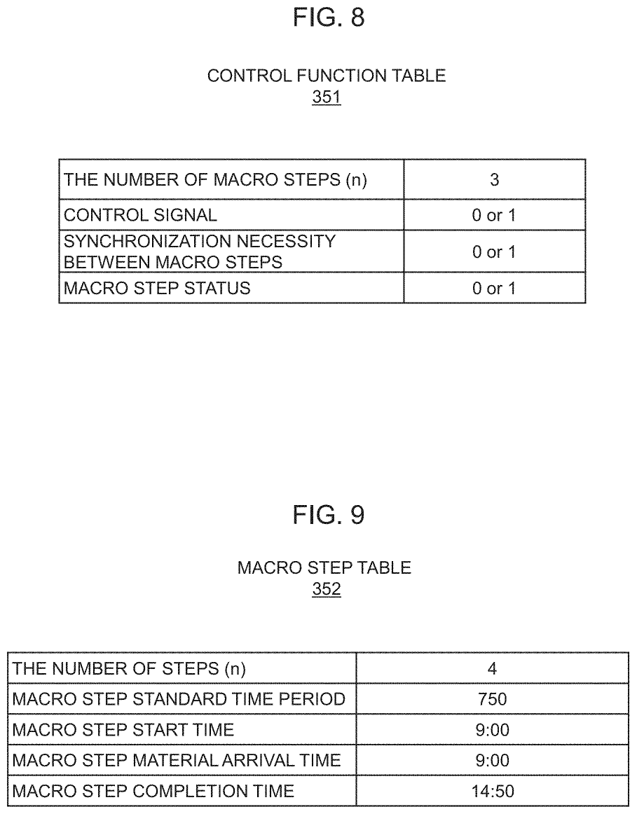

FIG. 8 shows a configuration example of the control function table 351.

The control function table 351 is a table for controlling the control function 81. Presence or absence of activation of each function that the control function 81 has, and at least part of the content of the process to be executed by the control function 81 are based on the control function table 351. The control function table 351 includes, for example, the following information.
The number of macro steps controlled by the control function 81.
A flag of whether or not the control function 81 switches the control signal between the ON state and OFF state (when the flag is “1”, the control signal is switched between the ON state and the OFF state).
A flag of necessity of synchronization of macro steps (when the flag is “1”, the macro steps are synchronized).
A flag of whether to output the status of the macro step or not (when the flag is “1”, the step number in execution while the macro step is executed is output).

FIG. 9 shows a configuration example of the macro step table 352.

The macro step table 352 is present for each macro step, for example. A certain macro step is exemplified. The macro step table 352 is a table representing the property of the macro step. The macro step table 352 includes, for example, the following information.
The number of steps included in the macro step.
The standard time period, start time and completion time of the macro step.
The arrival time of the material to be input into the macro step.

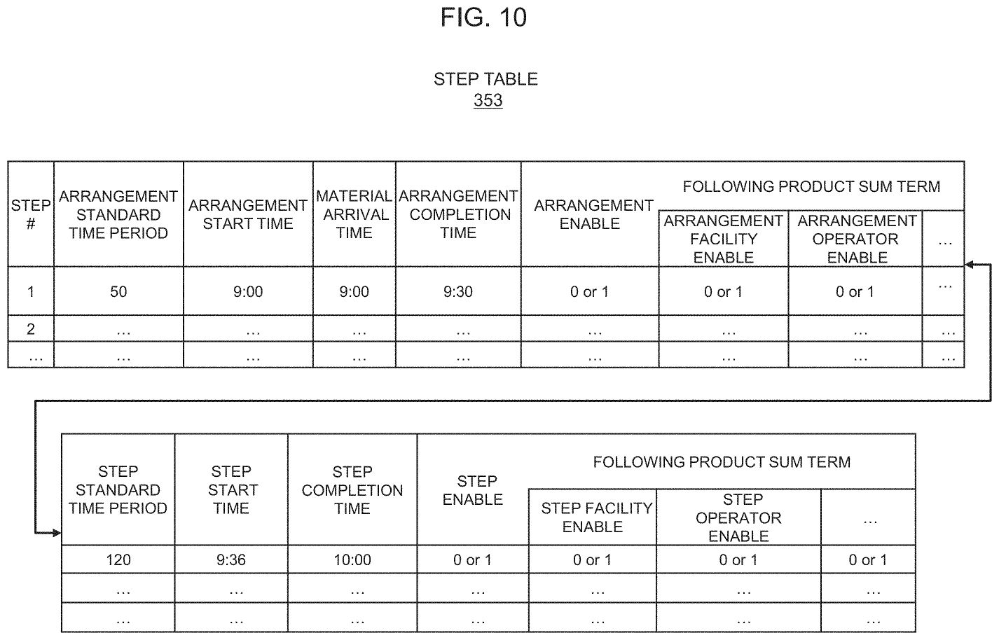

FIG. 10 shows a configuration example of the step table 353.

The step table 353 is present for each macro step, for example. A certain macro step is exemplified. The step table 353 is a table representing the property of each step included in the macro step. The step table 353 includes, for example, the following information with respect to each step.
The arrival time of the material.
The standard time period, start time and finish time of the arrangement.
For each resource of the arrangement, a flag of whether or not to output a signal representing the operation availability of the resource (when the flag is “1”, the signal of the operation availability is output).
The standard time period, start time and finish time of the step.
For each resource of the step, a flag of whether or not to output a signal representing the operation availability of the resource (when the flag is “1”, the signal of the operation availability is output).

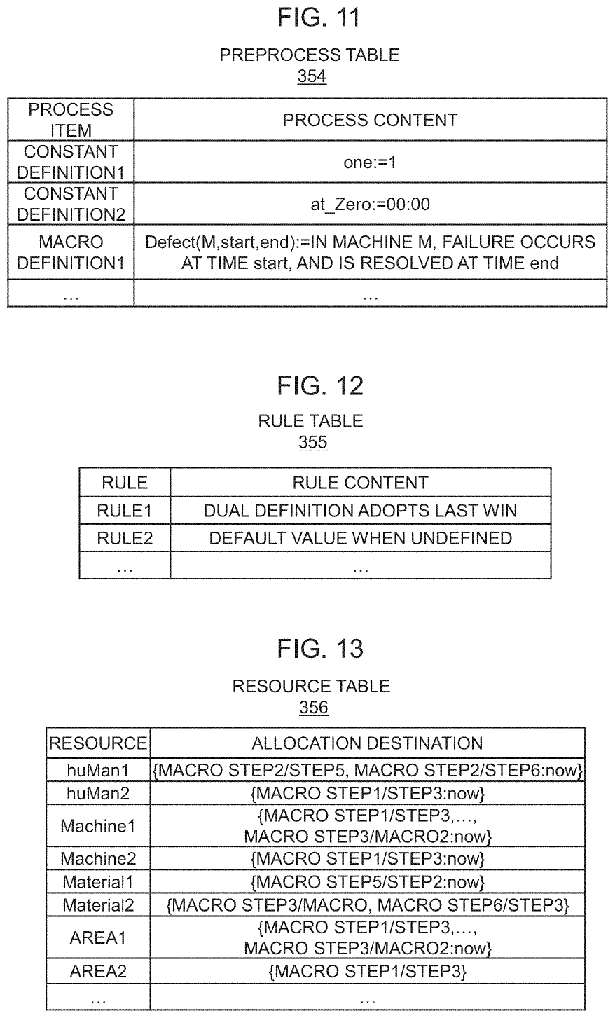

FIG. 11 shows a configuration example of the preprocess table 354.

The preprocess table 354 is a table for the preprocess 91 exemplified in FIG. 3 (for example, checking presence or absence of contradiction with the pseudo model of the scenario). For example, the preprocess table 354 includes information representing the definition for each macro step in the pseudo model 80.

FIG. 12 shows a configuration example of the rule table 355.

The rule table 355 represents the rule in the description of the scenario, for example, a method of resolving double definition description, and a default value for an undesignated variable. At least part of the rule table 355 may be used for the preprocess 91.

FIG. 13 shows a configuration example of the resource table 356.

The resource table 356 is a table representing a potential allocation destination (i.e., an element that can be an allocation destination), and the current allocation destination, with respect to each resource to be a visualization target. The allocation destination may be the entire macro step, or an arrangement or a step in the macro step.

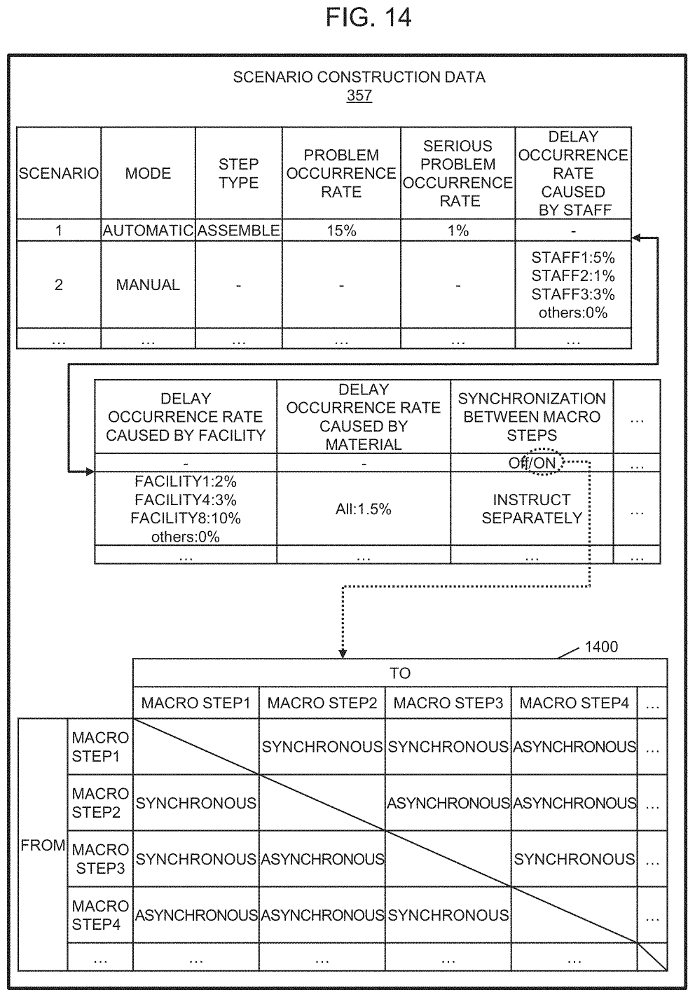

FIG. 14 shows a configuration example of the scenario construction data 357.

The scenario construction data 357 is data input into the scenario constructor 304 for constructing the scenario data 358. The scenario construction data 357 is data for constructing one or more scenarios with respect to one pseudo model 80. The scenario construction data 357 is an example of data that designates a factor of occurrence of the delay of the product, and the delay occurrence rate. The scenario construction data 357 includes, for example, the following information on a scenario-by-scenario basis.
Whether the scenario is constructed automatically or manually.
A cause of delay occurrence (e.g., resources, such as people (huMan), facility (Machine), and material (Material)).
The delay occurrence rate (e.g., the resource as the cause, and the delay occurrence rate) with respect to each cause of delay occurrence.
Presence or absence of synchronization of the macro step.

As definition of “delay occurrence rate”, any definition may be adopted. For example, “delay occurrence rate” may be the number of products that delay with respect to the total number of products in the pseudo model 80. Specifically, for example, in a case where the total number is “100”, “facility 1: 2%” may be such that the number of products about which delay is caused by the facility 1 is “2”.

In a case where the synchronization of the macro step is present (“ON”), the scenario construction data 357 includes a macro step synchronization table 1400. The macro step synchronization table 1400 represents that synchronization or asynchronization for each macro step. Note that according to the example shown in FIG. 14, the number of synchronized macro steps is two.

Alternatively, there may be a case where three or more macro steps are synchronized with each other.

In this embodiment, the scenario constructor 304 constructs the scenario data 358 on the basis of the scenario construction data 357. Accordingly, the load of scenario construction on the user is reduced, which in turn achieves support for scenario construction. The scenario represented by the constructed scenario data 358 is a scenario in which items designated by the scenario construction data 357 (e.g., the cause of product delay occurrence, and the delay occurrence rate) are reflected. Accordingly, the user is expected to obtain an intended scenario without detail scenario setting. Note that instead of or in addition to the scenario construction data 357, the scenario constructor 304 may construct the scenario data 358 on the basis of knowledge data (e.g., a database of knowledge in the OT-side process). The constructed scenario data 358 is stored in the storage device 252.

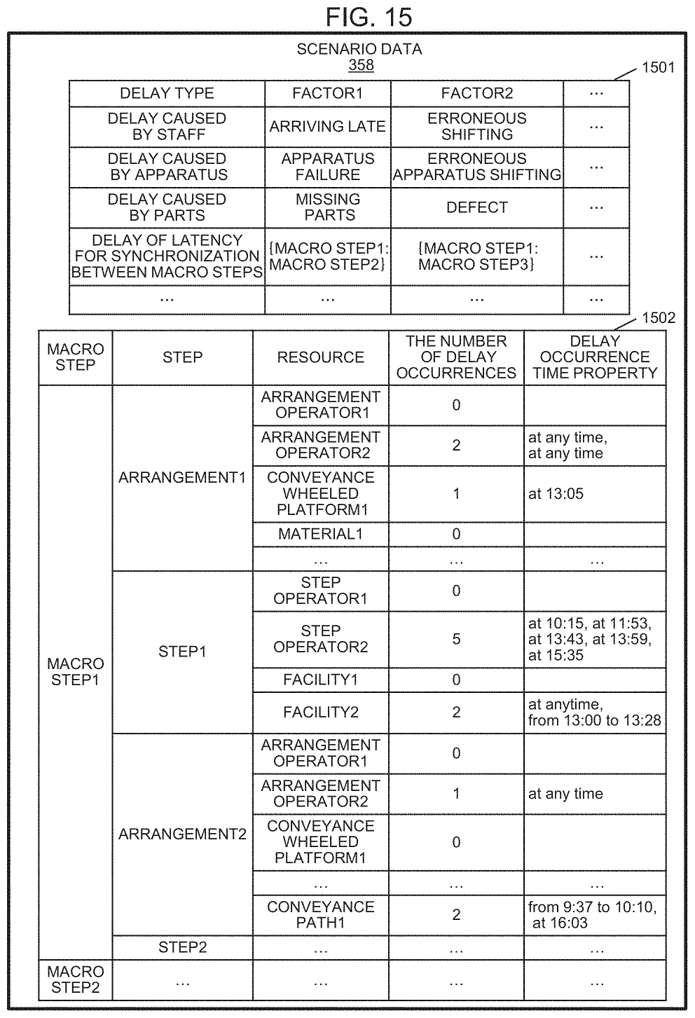

FIG. 15 shows a configuration example of the scenario data 358.

The scenario data 358 represents a scenario of the pseudo model 80. The scenario data 358 is present on a scenario-by-scenario basis, for example. For example, the scenario may be any of the following (a) to (e).

(a) A scenario reproducing past execution of the on-site process (a scenario for obtaining pseudo execution data having the same content as data as a result of past actual execution of the on-site process).
(b) A scenario for obtaining pseudo execution data as a likely execution result of the on-site process.
(c) A scenario of appropriately causing product delay in execution of the pseudo model 80.
(d) A scenario causing the scenario of the pseudo model 80 to depend on the pseudo model executor 342 (a scenario causing the pseudo model executor 342 to substantially define the scenario).
(e) A scenario causing no delay at all in execution of the pseudo model 80.

According to the example in FIG. 15, the scenario represented by the scenario data 358 is the (c) type scenario. Specifically, for example, the scenario data 358 includes at least scenario detail data 1502 of scenario profile data 1501 and the scenario detail data 1502. Note that the scenario data 358 is generated by the scenario constructor 304. Alternatively, the data may be prepared manually. In any way, the scenario data 358 may be data including the scenario detail data 1502.

The scenario profile data 1501 represents the profile of the scenario. The profile of the scenario is, for example, one or more factors belonging to causes of delay occurrence, with respect to each delay type (cause of delay occurrence).

The scenario detail data 1502 represents details of the scenario. The details of the scenario may, for example, include the followings.
One or more macro steps represented by the pseudo model 80.
For each macro step, one or more macro step elements that are elements of the macro step, specifically, arrangements or steps.
For each macro step element, one or more resources related to the macro step element.
For each resource, the number of delay occurrences, and the property of the delay occurrence time. The delay occurrence time property may be a property to which the number of delay occurrences is applied. For example, in a case where the number of delay occurrences is “X”, the delay occurrence time property may include X elements.

For each resource, the number of delay occurrences, and the delay occurrence time property are determined by the scenario constructor 304 on the basis of the delay occurrence rate corresponding to the resource (the delay occurrence rate represented by the scenario construction data 357). The scenario constructor 304 may be, for example, a machine learning model, such as a neural network. Machine learning with the machine learning model may be performed with at least part of knowledge data (e.g., past cases, data such as on the same industry, another line in the same company) being adopted as training data. At least part of the knowledge data described above may be adopted as at least part of the scenario construction data 357.

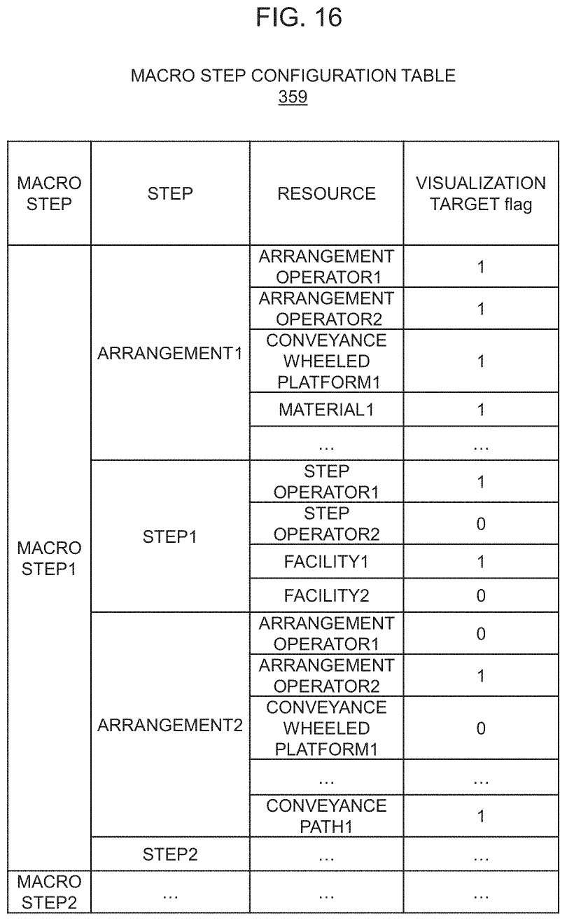

FIG. 16 shows a configuration example of the macro step configuration table 359.

The macro step configuration table 359 represents the visualization target resource. Specifically, for example, for each macro step element in the pseudo model 80, with respect to each resource related to the macro step element, the macro step configuration table 359 includes a flag of whether the resource is a visualization target or not.

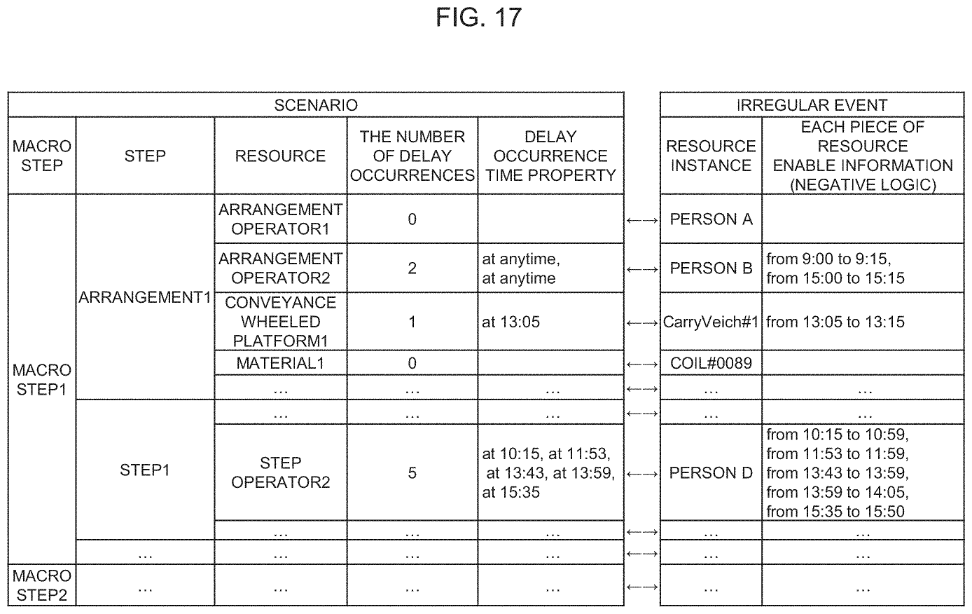

FIG. 17 schematically shows an example of instantiation of the scenario.

The instantiation of the scenario includes resource instantiation in the scenario, and instantiation of the delay occurrence time.

The “resource instantiation” is allocation of a resource instance to a resource. According to the example shown in FIG. 17, a resource instance “PERSON B” is allocated to a resource “ARRANGEMENT OPERATOR 2” (an example of huMan). For example, for each pair of the macro step element (arrangement or step) and the resource, one or more allocatable resource instances may be described in certain data (e.g., the resource table 356), and based on the data, one or more allocatable instances may be selected, and the selected one or more resource instances may be allocated to the pair of the macro step element and the resource.

The “instantiation of the delay occurrence time” is allocation of the instance of the delay occurrence time to the resource on the basis of the delay occurrence time property. According to the example shown in FIG. 17, delay occurrence times “from 9:00 to 9:15, from 15:00 to 15:15” are allocated to the resource “ARRANGEMENT OPERATOR 2” (the example of huMan) on the basis of the delay occurrence time property “at anytime, at anytime”. Note that at the delay occurrence time, values of “from” and “to” (i.e., the delay occurrence time, and the time period of occurrence of the delay) may be defined in the pseudo model 80 (e.g., the resource table 356) on a resource-by-resource basis, and the delay occurrence time may be instantiated in accordance with the definition.

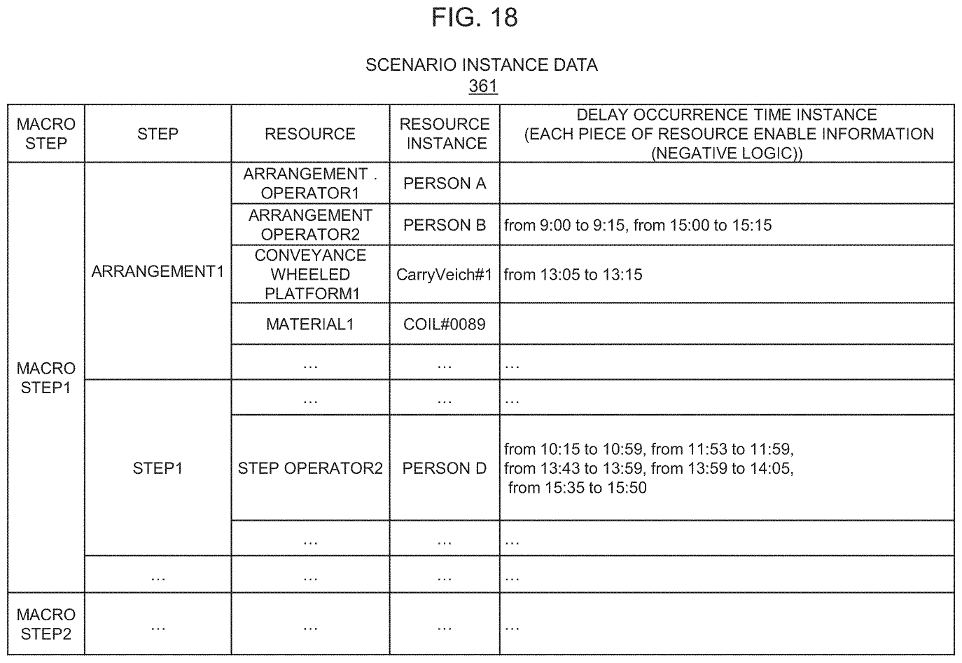

FIG. 18 shows a configuration example of the scenario instance data 361.

The scenario instance data 361 includes data in which a result of instantiation of the scenario is reflected, in the scenario detail data 1502. That is, the scenario instance data 361 represents the allocated resource instance and delay occurrence time instance, for each resource related to each macro step element in the pseudo model 80.

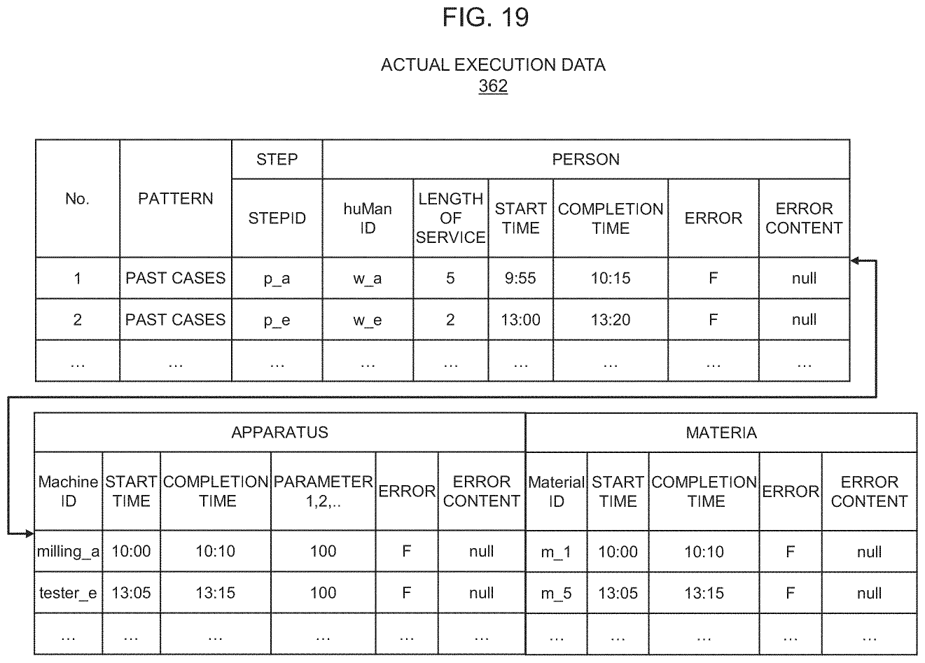

FIG. 19 shows a configuration example of the actual execution data 362.

The actual execution data 362 is data as a result of actual execution of the on-site process. The actual execution data 362 includes, for example, the start time and finish time, presence or absence of an error (“T” indicates presence of an error), and the content of the error, for each resource, with respect to each arrangement or each step. As for the arrangements and steps, the start time of a resource having the earliest start time among resources related to the arrangements and steps may be the start time of the arrangement or the step. As for the arrangements and steps, the completion time of a resource having the latest completion time among resources related to the arrangements and steps may be the completion time of the arrangement or the step. A production ID may be associated with each arrangement or each step.

The actual execution data 362 may include information representing the profile of at least one resource. For example, when the resource is “huMan”, the profile of the resource may be the length of service of a resource instance allocated to the resource. Data including a pattern obtained as a result of analysis of the accumulated actual execution data 362 is stored as knowledge data, and is used for scenario construction.

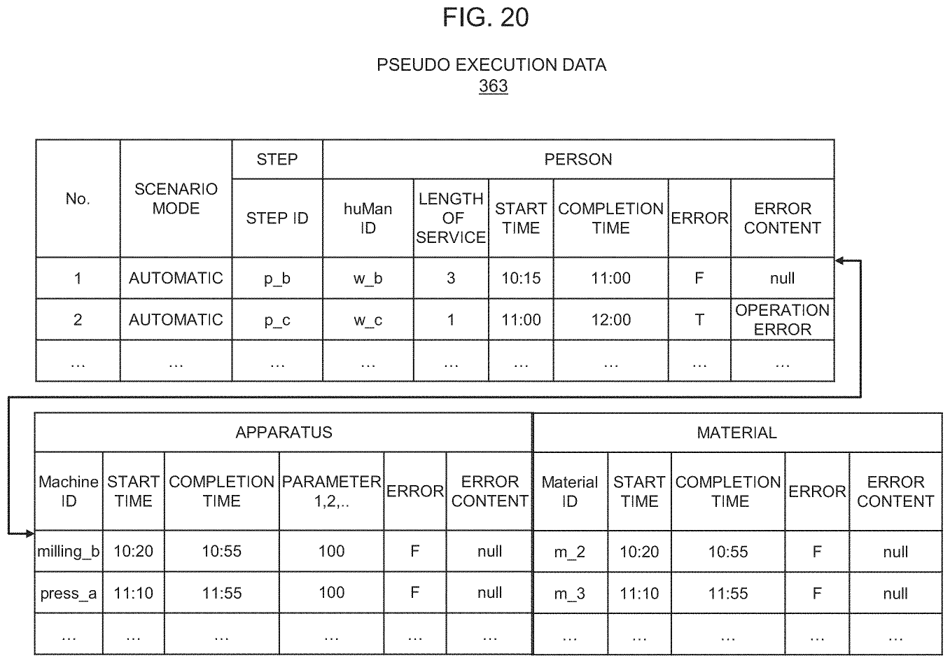

FIG. 20 shows a configuration example of the pseudo execution data 363.

The pseudo execution data 363 is data as an execution result of the pseudo model 80. The pseudo execution data 363 includes, for example, the start time and finish time, presence or absence of an error (“T” indicates presence of an error), and the content of the error, for each resource, with respect to each macro step element (arrangement or step). As for each of macro step elements, the start time of a resource having the earliest start time among resources related to the macro step elements may be the start time of the macro step element. As for each of macro step elements, the completion time of a resource having the latest completion time among resources related to the macro step elements may be the completion time of the macro step element. The pseudo execution data 363 may also include information representing the profile of at least one resource. A production ID may be associated with each macro step element.

The configurations of the actual execution data 362 and the pseudo execution data 363 are not limited to the examples shown in FIGS. 19 and 20. For example, each of the data 362 and data 363 may include data that represents the start time and finish time of the arrangement or step and presence or absence of an error for each resource pertaining to the arrangement or step, on a product-by-product basis (for example, for each production ID).

According to the example shown in FIG. 20, the pseudo execution data 363 represents the step, time and resource where an error (e.g., a delay or a cause of the delay) occurs. The IT executor 302 displays a chart (e.g., a diagram chart or a Gantt chart) representing the relationship between the arrangement and step and the time period, on the basis of the pseudo execution data 363. In the chart, a part corresponding to an arrangement or a step and a time where an error (e.g., a delay or the cause of the delay) occurs is highlighted. In the example shown in FIG. 20, a part corresponding to step ID “p_c” (or huMan ID “w_c”) and time from “11:00” to “12:00” indicates an error “T”, and is highlighted accordingly. A highlighted example is exemplified in FIG. 3. The highlighted display may be relatively highlighted one (i.e., the display may be increase in display intensity of the corresponding point, or reduction in display intensity of the non-corresponding point). The highlighted display may be various highlighted displays, such as thickening the color, and displaying a mark, instead of or in addition to thickening the line segment. As described above, based on the pseudo execution data 363, the error point is highlighted. Accordingly, before the on-site process is actually (or experimentally) executed, the user can predict a point with a high possibility of error occurrence (e.g., an arrangement or a step, and a time).

Hereinafter, an example of a process performed in this embodiment is described.

The scenario constructor 304 constructs the scenario data 358 on the basis of the scenario construction data 357 (and/or the knowledge data described above). The scenario input unit 341 receives the scenario data 358 constructed by the scenario constructor 304 (or generated by the user instead of the scenario constructor 304), and the pseudo model executor 342 executes the pseudo model 80 on the basis of the scenario data 358. Execution of the pseudo model 80 includes execution of the preprocess 91, the scheduling process 92, the instantiation process 93 and the main process 94 described above.

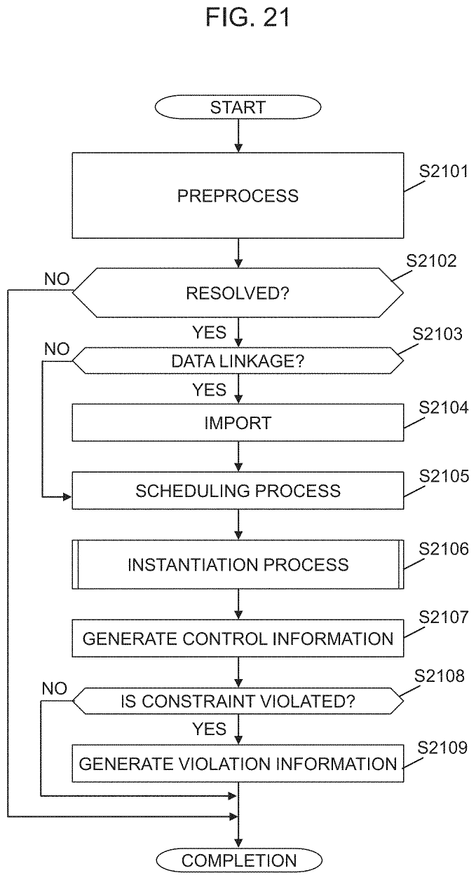

FIG. 21 shows an example of a flow of processes including the preprocess 91, the scheduling process 92, and the instantiation process 93.

In S2101, the pseudo model executor 342 performs the preprocess 91 in accordance with the preprocess table 354. The preprocess 91 may include, for example, at least one of a process of making a variable constant, and a macro expansion process. In S2101, for example, the pseudo model executor 342 determines whether the scenario data 358 is contradicted or not, that is, determines presence or absence of a statically found contradiction (found without execution of each step in a simulated manner). An example of the contradiction may be that a time period required for a certain step (a time period from the start time to the completion time) is less than the standard time period defined in the pseudo model 80, or an event that is incompatible in the scenario is described.

If there is a contradiction and the contradiction is a contradiction that can be resolved in accordance with the rule table 355, or there is no contradiction (S2102: YES), the processing proceeds to S2103. If there is a contradiction and the contradiction cannot be resolved (S2102: NO), the processing is completed.

In S2103, the pseudo model executor 342 determines whether linkage with the actual execution data 362 is required or not on the basis of the scenario data 358, for example. If the determination result of S2103 is true (S2103: YES), the processing proceeds to S2104. If the determination result of S2103 is false (S2103: NO), the processing proceeds to S2105. Here, to simplify description, the linkage target is the actual execution data 362. Alternatively, the linkage target may be other data, for example, other pseudo execution data 363, instead of or in addition to the actual execution data 362. That is, for example, multiple pseudo models 80 may be simultaneously executed.

In S2104, the pseudo model executor 342 imports schedule data representing the actual schedule of the on-site process. When the pseudo model executor 342 identifies the resource to be actually used in the on-site process from the schedule data, at least one of reference and update of at least one of the control function table 351 and the resource table 356 is performed, in order to avoid allocating the resource during pseudo model execution.

In S2105, the pseudo model executor 342 performs the scheduling process 92. In S2105, for example, the pseudo model executor 342 refers to the control function table 351, the step table 353 and the resource table 356, and creates a plan of using the resource so as to satisfy the limitation of the amount of resources and the use condition limitation. At least one of the control function table 351, the step table 353 and the resource table 356 may be appropriately updated.

In S2106, the pseudo model executor 342 performs the instantiation process. In S2106, for example, the pseudo model executor 342 allocates an irregular event (e.g., the resource instance, and the delay occurrence time instance) to the resource, on the basis of the result of scheduling in S2105. Accordingly, in the step table 353, an enable flag for each resource is changed from “0” to “1” (i.e., the value of the enable flag is changed to a value representing allocation of the irregular event).

In S2107, the pseudo model executor 342 allocates a synchronization operation (a synchronization operation of the macro step) to the control signal of the control function table 351, on the basis of the result of scheduling in S2105. Accordingly, the value of the control signal in the control function table 351 is changed from “0” to “1”, and although not shown, the specific content of the synchronization operation is associated with the control signal. In S2107, one or more time periods where the control signal for the macro step is in the ON state (the start time and the completion time of each time period) may be determined.

In S2108, the pseudo model executor 342 determines whether or not there is a violation of the scenario (constraint) represented by the scenario data 358. The determination may be, for example, determination of whether or not the result of scheduling in S2105 includes a violation of the scenario represented by the scenario data 358. If the determination result of S2108 is true (S2108: YES), in S2109 the pseudo model executor 342 generates scenario violation information representing a violation of the scenario (constraint). For example, the scenario violation information may be information representing the content of scenario violation (e.g., details of the type of violation), and the pseudo model executor 342 may output the generated scenario violation information (for example, display the information on the display device 223).

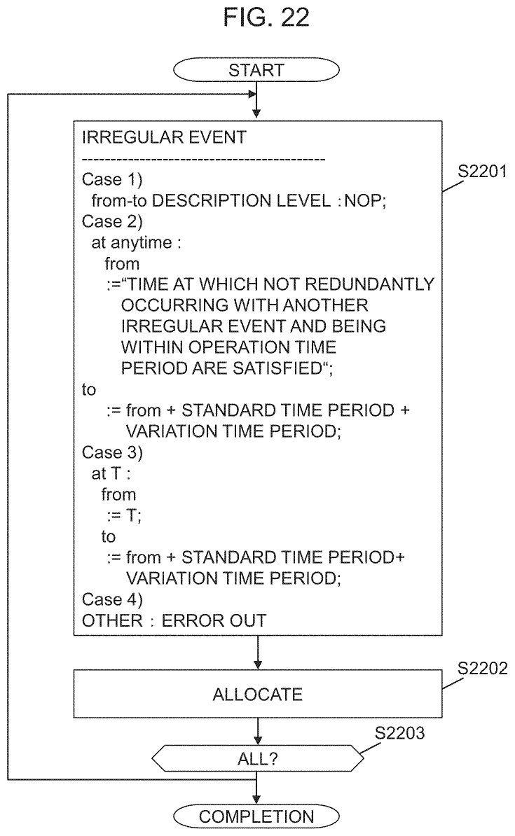

FIG. 22 shows an example of the flow of S2106 (instantiation process) of FIG. 21.

In S2201, the pseudo model executor 342 identifies the resource having not been allocated in the scenario data 358, and performs a process corresponding to the resource and the form (case) of the delay occurrence time property. The process to be performed here includes determination of the resource instance that is an allocation target from among resource instances allocatable to the resource, and determination of the delay occurrence time as an instance in the delay occurrence time property. With each macro step element, each resource, or each pair of a macro step element and a resource, various definitions about allocation may be associated. Based on the definitions, the instance to be allocated may be determined. For example, for each macro step element, each resource, or each pair of a macro step element and a resource, various time periods, such as the standard time period and the variation time period (or another type of information in addition to the time period), may be defined in the pseudo model 80, and based on the time period (and/or the other type of information), the resource instance and the delay occurrence time instance are determined.

In S2202, the pseudo model executor 342 allocates the instance determined in S2202 to the resource determined in S2202 (S2202). For example, the value of the resource enable in the step table 353 is changed to “1”.

In S2203, the pseudo model executor 342 determines whether or not S2201 is performed for all the resources represented by the scenario data 358. If the determination result of S2203 is false (S2203: NO), the processing returns to S2201.

According to the above description, the scenario is, for example, as follows.

The pseudo model 80 may include the start time and the completion time of the macro step element (arrangement or step), and the relationship between the resource and the macro step element. The resource related to each of the one or more macro step elements may be at least one of the resource as an object itself, and the resource for a process for an object. The scenario may be at least one delay, with respect to each of the one or more macro step elements, of a delay caused by an object related to the macro step element, and a delay caused by the resource related to the macro step element. Such a configuration can cause a delay by a desired cause in simulated execution of the on-site process. The pseudo execution data 363 in accordance with occurrence of such a cause is used to execute the IT-side process. Accordingly, appropriate check of a visualization system to be constructed, and feedback to the OT-side process are expected.

The pseudo model 80 includes an execution order of a plurality of macro steps. Each of the macro steps includes one or more macro step elements where the execution order is specified. The scenario includes a delay caused by latency for synchronization between two or more macro steps. Accordingly, in execution of the pseudo model 80, a delay caused by latency for synchronization between macro steps is intentionally caused, and a result of the delay is reflected in the pseudo execution data 363. Accordingly, the user can predict a result that can occur when a delay caused by latency for synchronization between macro steps occurs.

The OT executor 301 performs the preprocess 91. The preprocess 91 may include the followings. Accordingly, when the scenario represented by the scenario data 358 prepared separately from the pseudo model 80 has a part that does not match the pseudo model 80, it is expected to resolve the part and execute the pseudo model 80.
Determination of presence or absence of a contradiction in the scenario represented by the scenario data 358, based on the pseudo model 80.
Resolving the contradiction when the determination is true and the contradiction is allowed to be resolved within a range of a rule represented by the rule table 355 (an example of a predetermined rule).

The OT executor 301 performs the instantiation process 93. The instantiation process 93 may include the followings. Accordingly, the resource and the instance of the occurrence time are not required to be included in the scenario. Consequently, the load of constructing the scenario data 358 can be reduced.
Allocation of an instance of each resource represented by the scenario, to the resource, based on the pseudo model 80 and the scenario data 358.
Allocation of an occurrence time of the delay to the resource where the delay occurs among the resources represented by the scenario.

By performing the instantiation process 93, the scenario instance data 361 where the resource instance and the delay occurrence time instance are allocated to the pair of the step and the resource is constructed. The main process 94 is performed based on the scenario instance data 361.

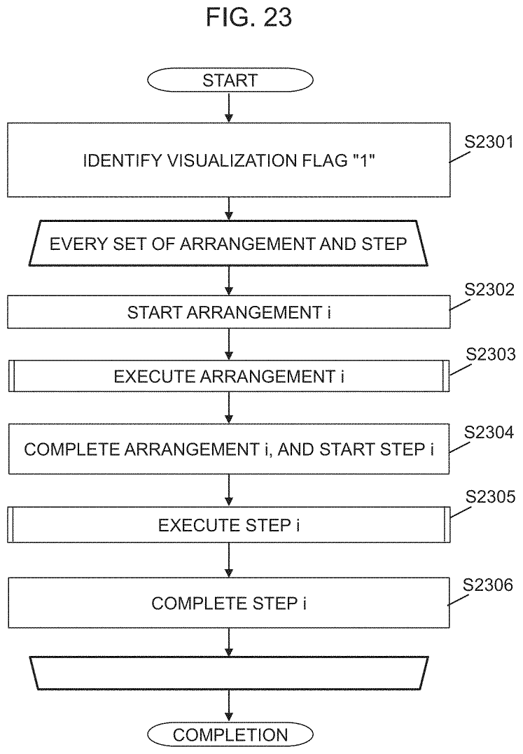

FIG. 23 shows an example of a flow of the main process 94.

In 52301, the pseudo model executor 342 refers to the macro step configuration table 359, and identifies the visualization target resource. Instead of reference to the macro step configuration table 359, for example, the following process may be performed. The pseudo model executor 342 may identify the resource selectable as the visualization target on the basis of the scenario data 358, and display, through the UI unit 303, the UI that displays the identified selectable resources in a selectable manner. The pseudo model executor 342 may receive designation of the visualization target resource through the UI, thereby identifying the visualization target resource.

As for the visualization target resources, with respect to every pair of the arrangement and the step, S2302 to S2306 are performed. A pair of an arrangement i (an arrangement for a step i) and the step i (a step having a step number i) is exemplified.

The pseudo model executor 342 starts the arrangement i (S2302), and executes the arrangement i (S2303).

The pseudo model executor 342 completes the arrangement i and starts the step i (S2304), executes the step i (S2305), and completes the step i (S2306).

The start time and the completion time of the arrangement i, and the start time and the completion time of the step i are based on the step table 353.

Specifically, for example, the completion time of each of the arrangement i and the step i depends on a time period that is AND (logical conjunction) between a time period where the enable signal about the arrangement i or the step i is in the ON state and a time period where the control signal from the control function 81 is in the ON state.

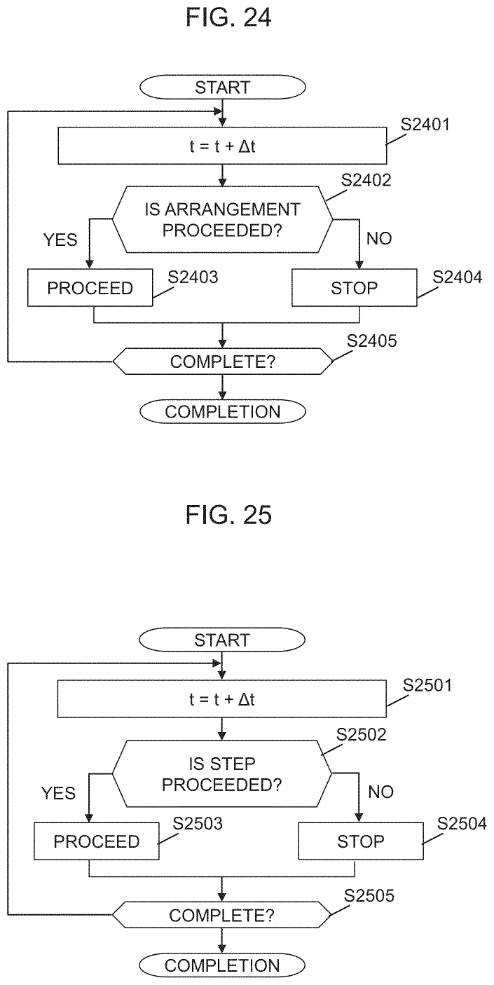

FIG. 24 shows an example of a flow of S2303 (arrangement execution) of FIG. 23.

In S2401, the pseudo model executor 342 adds Δt to the start time t of the arrangement i. This “Δt” is a unit time period (a time period of a unit process) defined in the pseudo model 80 for the arrangement i. The unit time period may be common among all the arrangements.

In S2402, the pseudo model executor 342 determines whether to advance the arrangement i or not. The determination of S2402 may be, for example, determination of whether both the enable signal of the arrangement i and the control signal at t after execution of S2401 are in the ON state or not. The enable signal of the arrangement i may be in the ON state, when the enable signals of at least one or all of resources pertaining to the arrangement i are in the ON state, or when the enable signals of one or all of the visualization target resources pertaining to the arrangement i are in the ON state. The relationship between the state of the enable signal of the arrangement i, the state of the control signal, and the time may be defined in the pseudo model 80.

If the result of determination of S2402 is true (S2402: YES), in S2403 the pseudo model executor 342 proceeds the arrangement i. If the result of determination of S2402 is false (S2402: NO), in S2404 the pseudo model executor 342 stops the arrangement i.

In S2405, the pseudo model executor 342 determines whether all the unit processes constituting the arrangement i are finished or not. If the result of determination of S2405 is true (S2405: YES), the arrangement i is completed. If the determination result of S2405 is false (S2405: NO), the processing returns to S2401.

FIG. 25 shows an example of a flow of S2305 (step execution) of FIG. 23.

In S2501, the pseudo model executor 342 adds At to the start time t of the step i. This “At” is a unit time period (a time period for a unit process) defined in the pseudo model 80 for the step i. The unit time period may be common among all the steps.

In S2502, the pseudo model executor 342 determines whether to advance the step i or not. The determination of S2502 may be, for example, determination of whether both the enable signal of the step i and the control signal at t after execution of S2501 are in the ON state or not. The enable signal of the step i may be in the ON state, when the enable signals of at least one or all of resources pertaining to the step i are in the ON state, or when the enable signals of one or all of the visualization target resources pertaining to the step i are in the ON state. The relationship between the state of the enable signal of the step i, the state of the control signal, and the time may be defined in the pseudo model 80.

If the result of determination of S2502 is true (S2502: YES), in S2503 the pseudo model executor 342 proceeds the step i. If the result of determination of S2502 is false (S2502: NO), in S2504 the pseudo model executor 342 stops the step i.

In S2505, the pseudo model executor 342 determines whether all the unit processes constituting the step i are finished or not. If the result of determination of S2505 is true (S2505: YES), the step i is completed. If the determination result of S2505 is false (S2505: NO), the processing returns to S2501.

By executing the main process 94, the pseudo execution data 363 is generated and stored in the storage device 252. Before the IT-side process is executed based on the pseudo execution data 363, presence or absence of an abnormality of the pseudo execution data 363 can be checked.

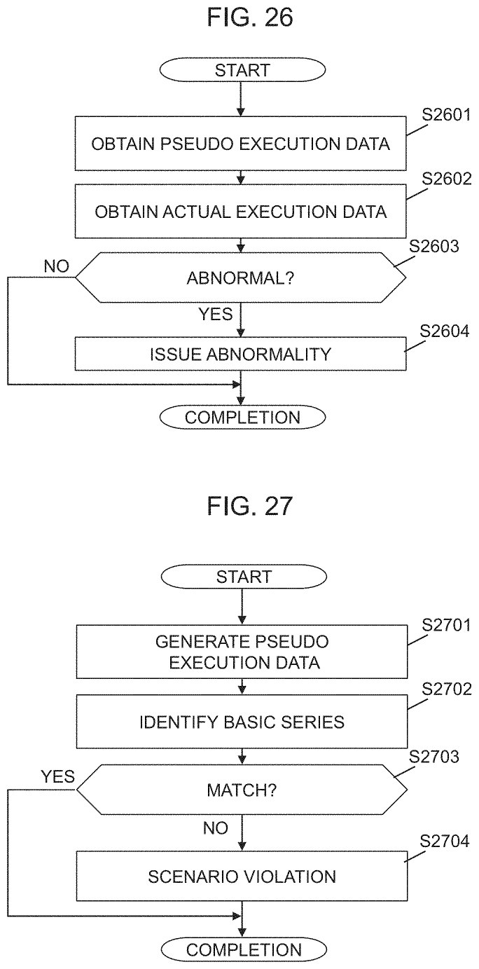

FIG. 26 shows an example of a flow of a process of checking the pseudo execution data 363.

In S2601, the pseudo model executor 342 obtains the pseudo execution data 363.

When the actual execution data 362 that is data as an actual execution result of the on-site process is in the storage device 252, in S2602 the pseudo model executor 342 obtains the actual execution data 362.

In S2603, the pseudo model executor 342 compares the pseudo execution data 363 obtained in S2601 with the actual execution data 362 obtained in S2602, and determines whether or not the difference between the pseudo execution data 363 and the actual execution data 362 satisfies a condition defined as an abnormality (S2603). The condition described here may be, for example, that the difference is equal to or larger than a certain amount. Furthermore, “abnormality” described here may be an abnormality in a narrow sense, i.e., an abnormality itself, or an abnormality in a broad sense including a predictor besides an abnormality itself.

If the determination result of S2603 is true (S2603: YES), in S2604 the pseudo model executor 342 issues an abnormality (i.e., outputs a notification of an abnormality).

According to the process exemplified in FIG. 26, the pseudo execution data 363 is compared with the actual execution data 362, thereby finding whether or not the pseudo execution data 363 includes a value having a high possibility of indicating an abnormality. Consequently, feedback to the OT-side process can be achieved so as to negate the value. Note that instead of or in addition to the actual execution data 362, another type of data indicating that the on-site process has been normally performed may be adopted as data compared with the pseudo execution data 363. A machine learning model learned based on data as a result of execution of a normal on-site process is prepared. The pseudo model executor 342 may input the pseudo execution data 363 into the machine learning model, and identify whether or not the pseudo execution data 363 includes a value having a high possibility of indicating an abnormality, from an output of the machine learning model.

The pseudo execution data 363 is generated by the main process 94. In generation of the pseudo execution data 363, the pseudo execution data 363 is appropriately changed. The change is change that violates the scenario in an acceptable range.

FIG. 27 shows an example of a flow of a process that is in the main process 94 and is a process of generating the pseudo execution data. The process exemplified in FIG. 27 is performed for each macro step, for example.

In S2701, the pseudo model executor 342 generates macro pseudo data that is pseudo execution data about the macro step, through execution of the macro step. The macro pseudo data generated in S2701 is temporary data.

In S2702, the pseudo model executor 342 identifies the basic series (e.g., fastest likely pattern data), from a given start time and finish time (e.g., times identified based on the step table 353) for each product (material) to enter the macro step. Specific examples of the basic series are described later.

In S2703, the pseudo model executor 342 determines whether data about the macro step immediately before or immediately after the macro step concerned in the execution order (e.g., pseudo execution data) matches the macro pseudo data on this macro step or not (S2703). The determination of S2703 may include, for example, at least one of determination of whether or not the completion time of the immediately previous macro step coincides with the start time of the macro step concerned with respect to each product (material), and determination of whether or not the start time of the immediately next macro step coincides with the completion time of the macro step concerned.

If the determination result of S2703 is false (S2703: NO), in 52704 the pseudo model executor 342 changes the macro pseudo data to data violating the scenario represented by the scenario data 358 in a range accepted for the scenario represented by the scenario data 358. Accordingly, the pseudo execution data that matches the pseudo execution data in previous and next macro steps can be generated. If matching with the pseudo execution data in the previous and next macro steps cannot be achieved even with change to data violating the scenario in the acceptable range (for example, the difference from the pseudo execution data in the previous and next macro steps is not less than a certain amount), the pseudo model executor 342 may issue an abnormality. With no limitation to such an example, in any way, when the pseudo model executor 342 generates data violating the scenario, this executor may generate scenario violation information representing content of the violation, and output the scenario violation information.

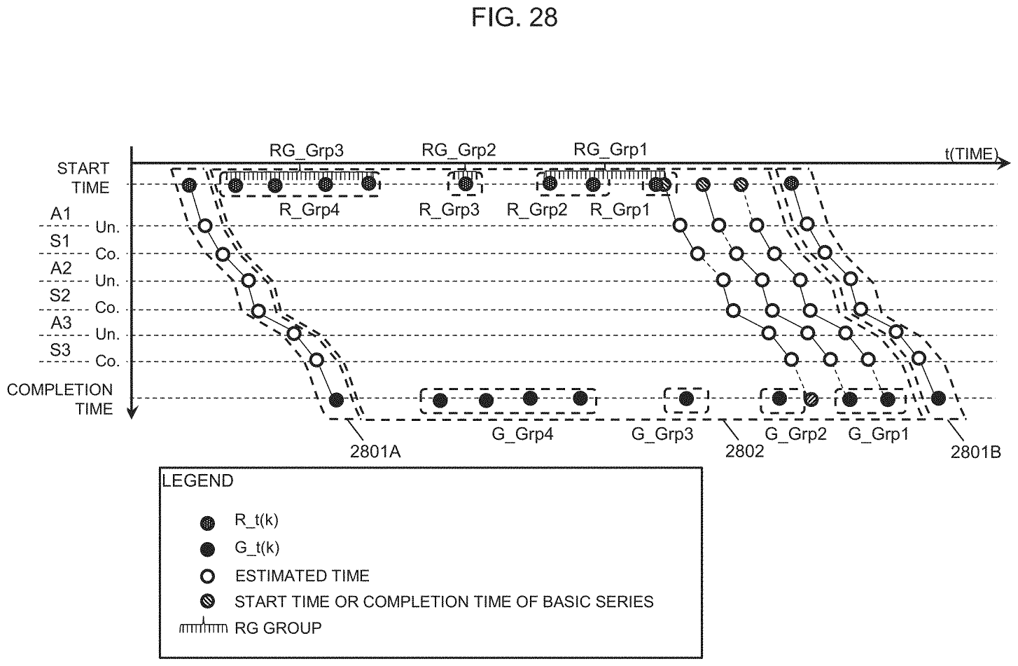

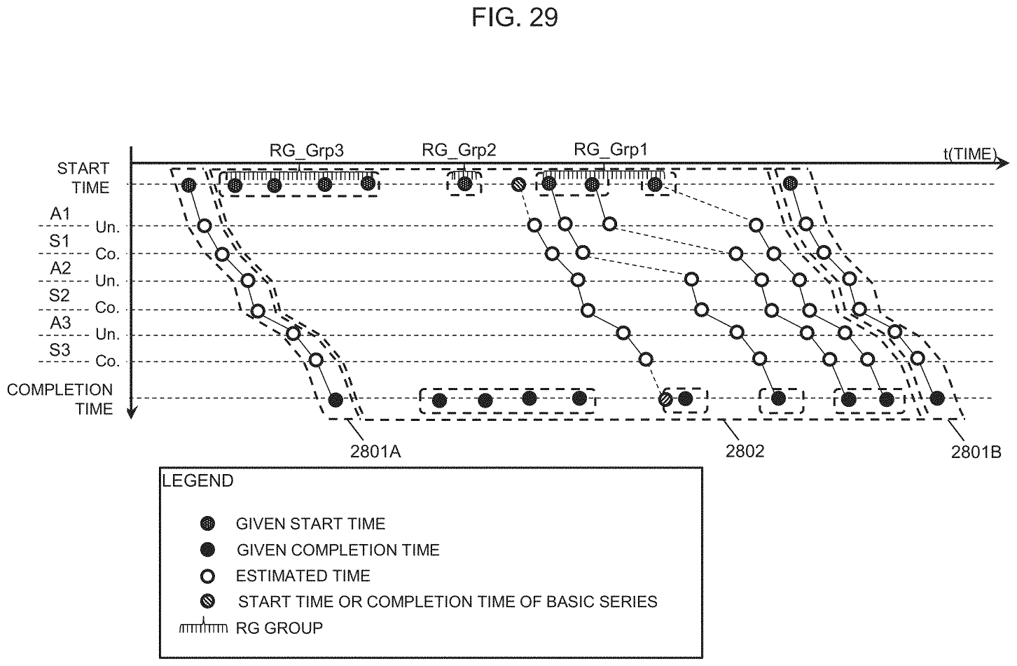

A specific example of the process of generating the pseudo execution data for each macro step is described with reference to FIGS. 28 to 30, for example. The following generation process is not limited to the process of generating the pseudo execution data according to the embodiment, and may be applicable to the entire process of generating data representing the pseudo execution result of the macro step, with respect to the given start time of the macro step (an example of a macro task), the given completion time of the macro step, and a case with the standard time period for each macro step element (an example of the macro step element) belonging to the macro step, on a product-by-product basis (an example of a target).

FIGS. 28 to 30 schematically show a specific example of the process of generating the pseudo execution data for one macro step. Note that in the description with reference to FIGS. 28 to 30, definitions of terms are as follows.
R_t(k): the start time of the macro step for a k-th product (the completion time of the final step in the previous macro step)
G_t(k): the completion time of the macro step for the k-th product (the start time of the first arrangement in the next macro step)
An in FIGS. 28 to 30: Arrangement n (n=1, 2, 3)
Sn in FIGS. 28 to 30: Step n (n=1, 2, 3)
Un. in FIGS. 28 to 30: Undertake
Co. in FIGS. 28 to 30: Complete

The pseudo model executor 342 calculates the basic series (fastest likely pattern), from at least one of the value of G_t(k)−R_t(k) and the given standard time period of each step i. For example, the basic series is a series which has the shortest difference between the standard time period of the macro step and the pseudo time period and whose start time and completion time for each macro step element are estimated on the basis of the standard time period of each macro step element (arrangement or step) of the macro step. The pseudo time period is the difference between the given start time and the given completion time of the macro step, and is the value of G_t(k)−R_t(k) here.

Next, the pseudo model executor 342 generates a delay present group 2802 and a delay absent group 2801. Specifically, for example, the followings are performed.
The pseudo model executor 342 compares the standard time period TST of the series (e.g., Σ(standard time period of arrangement i+standard time period of step i)) with the value of G_t(k)−R_t(k), with reference to the standard time periods of each arrangement i and each step i. The series satisfying TST*(1+α)>G_t(k)−R_t(k) is adopted as a standard series where no specific delay occurs in any arrangement i and any step i. α (error) may be adjusted (e.g., α=0 is allowed). Note that for each product, “series” is a set of times including R_t(k) (an example of the given start time) and G_t(k) (an example of the given completion time) of the macro step. The “series” may only include R_t(k) and G_t(k), or may further include an estimated time between R_t(k) and G_t(k) (the start time and/or completion time of the macro step element). The “estimated time” may be a time estimated from the pseudo model 80.
The pseudo model executor 342 adopts the standard series adjacent to each other, as series belonging to the delay absent group 2801. Furthermore, the pseudo model executor 342 adopts series that do not belong to the delay absent group 2801 and are adjacent to each other, as series belonging to the delay present group 2802. As a result, a set of one or more series that are between a standard series and the next standard series is the delay present group 2802. The group adjacent to the delay present group 2802 is the delay absent group 2801 that is a set of one or more standard series sequential in a time series manner (for example, R_t(k) sequential in a time series manner). One of the one or more standard series constituting the delay absent group 2801 is the basic series.

Next, for the delay present group 2802, the pseudo model executor 342 forms one or more R_groups, and one or more G_groups. The R group is a set of one or more R_t(k) sequential in a time series manner. The G group is a set of one or more G_t(k) sequential in a time series manner. Specifically, for example, the followings are performed.
The pseudo model executor 342 adopts, as the G group, those having the difference of G_t(k) adjacent to each other (specifically, the value of G_t(k+1)−G_t(k)) being less than TST*(1+a) described above.
The pseudo model executor 342 adopts, as the R group, those having the difference of Red_t(k) adjacent to each other (specifically, the value of Red_t(k+1)−Red_t(k)) being less than TST*(1+a) described above. For convenience sake, in the example shown in FIGS. 28 to 30, the G_groups in the delay present group 2802 are represented sequentially from the right as G_Grp1, G_Grp2, G_Grp3 and G_Grp4. Likewise, the R_groups in the delay present group 2802 are represented sequentially from the right as R_Grp1, R_Grp2, R_Grp3 and R_Grp4.
The pseudo model executor 342 generates RG_groups as upper level groups of series with a closed relationship between the G_groups and R_groups. No series belonging to the RG_group belongs to another RG_group. For convenience sake, in the example shown in FIGS. 28 to 30, the RG_groups in the delay present group 2802 are represented sequentially from the right as RG_Grp1, RG_Grp2 and RG_Grp3.

For each RG_group, the pseudo model executor 342 executes the followings. In the followings, for example, execution is performed sequentially from the right RG_group (RG_groups at later times). One RG_group and one delay present group 2802 are exemplified. The series in the delay present group 2802 is called “non-standard series”.
The pseudo model executor 342 arranges N basic series to the right with shortest intervals. N is equal to or less than the number of non-standard series constituting the RG_group (note that the maximum value is the number of steps×2+1). A m-th basic series among the N basic series is called “basic series m” (m is a natural number). The smaller m is, the later the start time of the series is. That is, the last basic series among the N basic series is the first basic series. The basic series and the non-standard series correspond to each other such that 1:1.
The pseudo model executor 342 moves the entire basic series m so as to overlay the completion time of the basic series m on the completion time of the corresponding non-standard series. During the movement, the slope of each line segment of the basic series is maintained.
The pseudo model executor 342 moves the entire upper level time group of the basic series m so as to overlay the start time of the basic series m on the start time of the corresponding non-standard series. The “upper level time group” includes times including the start time and to the m-th time. The first time is the start time. During the movement, the slope of each line segment in the upper level time group is maintained. In other words, among the line segments in the basic series m, only the line segment between the m-th time and the (m+1)-th time has a slope that changes.

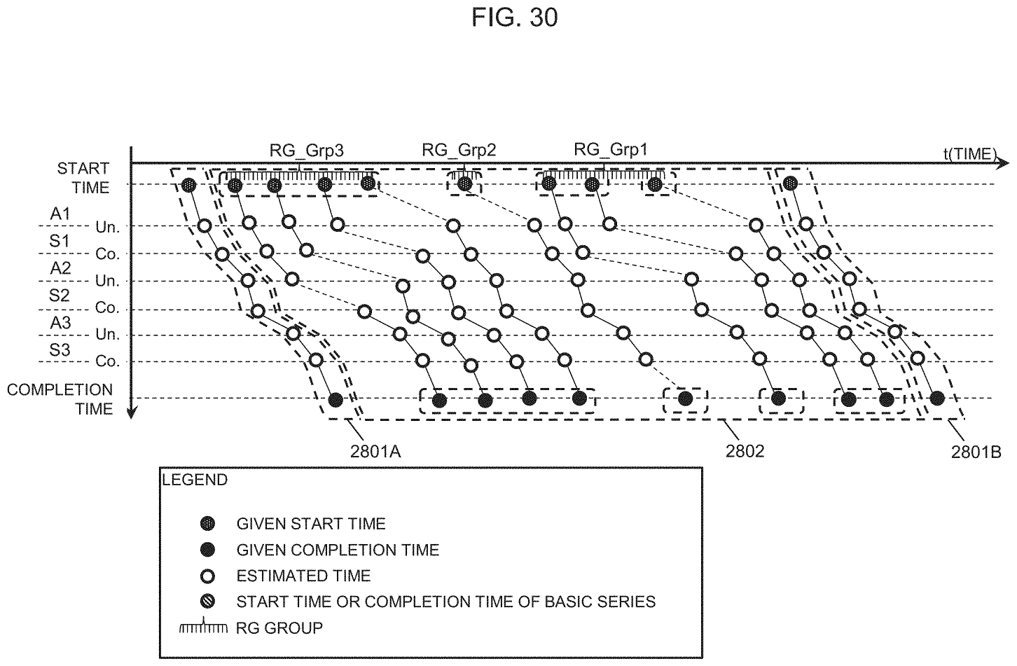

The process described above is performed for each delay present group 2802 with respect to each RG_group, thereby generating the pseudo execution data representing the times exemplified in FIG. 30. According to the example shown in FIGS. 28 to 30, the following likely pseudo execution result (pseudo execution data) can be generated; that is, a pseudo execution result can be generated where in the macro step, upon occurrence of a delay in a certain macro step element, the delay sequentially causes delays in former macro step elements.

The description in FIGS. 28 to 30 can be summarized as follows, for example.

That is, the OT executor 301 performs the following (A) to (C), in execution of the pseudo model 80. According to the following description, the process based on the basic series is achieved. Consequently, pseudo execution data as a likely pseudo execution result is expected to be generated.

(A) The OT executor 301 identifies the delay absent group, and the delay present group. The delay absent group is one or more standard series sequential in a time series manner. The delay present group is one or more non-standard series that are sequential in a time series manner. For each target (e.g., product), the series is a set of times that include a given start time and a given completion time of the macro task (e.g., a macro step). The standard series is a series where a difference between a standard time period and a pseudo time period of the macro task is equal to or less than a certain value. The standard time period is a standard value between the start time and the completion time of the macro task. The pseudo time period is a difference between the given start time and the given completion time of the macro task.
(B) Based on a basic series among the one or more standard series, for each of the one or more non-standard series in the delay present group, the OT executor 301 estimates a likely delay of the non-standard series. The basic series is a series where a difference between the standard time period and the pseudo time period of the macro task is shortest, and the start time and the completion time of each of the tasks is estimated based on the standard time of each of the tasks in the macro task.
(C) The OT executor 301 generates the pseudo execution data based on a result of estimation of (B).

In (B) described above, the OT executor 301 executes (b1) to (b3). According to the following description, upon occurrence of a delay in a certain task, a pseudo execution result where delays sequentially occur in former macro tasks is expected to be generated. (b1) The OT executor 301 identifies one or more start time groups (e.g., R_groups), and one or more completion time groups (e.g., G_groups). The start time group includes one or more given start times of the macro task that are sequential in a time series manner, and in the start time group, the difference between adjacent given start times is equal to or less than a certain value. The completion time group includes one or more given completion times of the macro task that are sequential in a time series manner, and in the completion time group, the difference between adjacent given completion times is equal to or less than a certain value.

(b2) The OT executor 301 identifies one or more start and completion groups (e.g., RG_groups). The start and completion group is a group that includes one or more start groups, and one or more completion groups. In the start and completion group, any given start time, and any given completion time are closed in the start and completion group.
(b3) For each start and completion group, the OT executor 301 executes (b3-1) and (b3-2).
(b3-1) The OT executor 301 sets N basic series of time series. For each of the start and completion groups, N is a natural number and a number that belongs to the start and completion group and is equal to or less than the number of non-standard series.
(b3-2) For each of N basic series, the OT executor 301 executes (b3-2-1) and (b3-2-2).
(b3-2-1) The OT executor 301 moves an entire m-th basic series that is the basic series so as to overlay the completion time of the m-th basic series on the completion time of the non-standard series corresponding to the m-th basic series.
(b3-2-2) The OT executor 301 moves an entire upper level time group of the m-th basic series so as to overlay the start time of the m-th basic series on the start time of the non-standard series corresponding to the m-th basic series. The first basic series is a basic series having the latest start time among the N basic series. For each basic series, the upper level time group includes times including the start time of the basic series to the m-th time, and the first time is the start time.

The one embodiment has been described above. This embodiment is an example to describe the present invention. There is no intention to limit the scope of the present invention only to this embodiment. The present invention can be executed in various modes.

For example, the present invention is applicable also to system construction other than system construction for a system of visualizing production activities, specifically, entire system construction that requires data as a result of the OT-side process for the IT-side process.

For example, S2601 to S2604 in FIG. 26 may be processes to which the following modified example is applied. That is, the pseudo model executor 342 executes the pseudo model 80 in parallel with (for example, simultaneously) actual execution in the manufacturing system 200 (an example of actual execution of the on-site process), thereby obtaining the pseudo execution data 363 (S2601). The pseudo model executor 342 obtains the actual execution data 362 input into the support system 100 accompanied by actual execution in the manufacturing system 200 (S2603). Based on the pseudo execution data 363 obtained in S2601 and the actual execution data 362 obtained in S2602, the pseudo model executor 342 determines whether or not the condition defined as an abnormality is satisfied or not (S2603). If the result of determination of S2603 is true (S2603: YES), in S2604 the pseudo model executor 342 issues an abnormality. According to this modified example, the pseudo execution data 363 is adopted as training data (e.g., data corresponding to a situation where ideal production is executed), and the abnormality of the actual execution data 362 can be detected. There is a case where it is difficult to immediately detect that the actual execution data 362 includes data representing occurrence of an abnormal state, when the actual execution data 362 is obtained. According to this modified example, by causing the ideally operating pseudo model to accompany actual execution, it is expected to detect that the actual execution data 362 includes data representing an abnormality or a predictor thereof.

We claim:

1. A support system supporting system construction that requires data as a result of an OT-side process that is a process on an OT (Operation Technology) side, for an IT-side process that is a process on an IT (Information Technology) side, the support system comprising:
an OT executor configured to execute a pseudo model that is a model simulating an on-site process that is at least part of the OT-side process, the on-site process including one or more tasks that start and finish for each of one or more targets; and
an IT executor configured to execute the IT-side process, based on pseudo execution data that is data obtained by execution of the pseudo model.

2. The support system according to claim 1,
wherein the OT executor executes the pseudo model, based on scenario data that represents a scenario including that any delay does not occur at all or a delay occurs in one or more tasks.

3. The support system according to claim 2,
wherein the pseudo model includes a start time and a completion time of the task, and a relationship between a resource and the task,
the resource related to each of the one or more tasks is at least one of the resource as an object itself, and the resource for a process for an object, and
the scenario is at least one delay, with respect to each of the one or more tasks, of a delay caused by an object related to the task, and a delay caused by the resource related to the task.

4. The support system according to claim 2,
wherein the pseudo model includes an execution order of a plurality of macro tasks,
each of the macro tasks includes one or more tasks where the execution order is specified, and
the scenario includes a delay caused by latency for synchronization between two or more macro tasks

5. The support system according to claim 2,
wherein the OT executor performs a preprocess, and the preprocess includes:
determination of presence or absence of a contradiction in the scenario represented by the scenario data, based on the pseudo model; and
resolving the contradiction when the determination is true and the contradiction is allowed to be resolved within a range of a predetermined rule.

6. The support system according to claim 3,
wherein the OT executor performs an instantiation process, and
the instantiation process includes:
allocation of an instance of each resource represented by the scenario, to the resource, based on the pseudo model and the scenario data; and
allocation of an occurrence time of the delay to the resource where the delay occurs among the resources represented by the scenario.

7. The support system according to claim 3,
wherein the pseudo model includes an execution order of a plurality of macro tasks, and a control function of controlling execution of the macro tasks,
each of the macro tasks includes one or more tasks where the execution order is specified,
the scenario is at least one delay of following (x) and (y),
(x) at least one delay, with respect to each of the one or more tasks, of a delay caused by an object related to the task, and a delay caused by the resource allocated to the task, and
(y) a delay caused by latency for synchronization between two or more macro tasks,
the preprocess, and the instantiation process are specified in the control function,
the OT executor performs the preprocess and the instantiation process that are specified in the control function,
the preprocess includes:
determination of presence or absence of a contradiction in the scenario represented by the scenario data; and
resolving the contradiction when the determination is true and the contradiction is allowed to be resolved within a range of a predetermined rule,
the instantiation process includes:
allocation of an instance of each resource represented by the scenario, to the resource, based on the pseudo model and the scenario data; and
allocation of an occurrence time of the delay to the resource where the delay occurs among the resources represented by the scenario, and
when generating data violating the scenario, the OT executor generates scenario violation information that is information representing content of the violation, and outputs the scenario violation information.

8. The support system according to claim 1,
wherein the pseudo execution data represents the delay, or the task and a time where the delay is caused,
the IT executor displays a chart that represents a relationship between the task and a time period, based on the pseudo execution data, and
in the chart, a part corresponding to the delay or the task and the time where the delay is caused is highlighted.

9. The support system according to claim 1,
wherein the pseudo model includes that each of the targets is through the tasks constituting a macro task,
in execution of the pseudo model, the OT executor
(A) identifies a delay absent group, and a delay present group,
the delay absent group is one or more standard series that are sequential in a time series manner,
the delay present group is one or more non-standard series that are sequential in a time series manner,
for each target, the series is a set of times that include a given start time and a given completion time of the macro task,
the standard series is a series where a difference between a standard time period of the macro task and a pseudo time period is equal to or less than a certain value,
the standard time period is a standard value between the start time and the completion time of the macro task,
the pseudo time period is a difference between the given start time and the given completion time of the macro task,
(B) based on a basic series among the one or more standard series, for each of the one or more non-standard series in the delay present group, a likely delay of the non-standard series is estimated,
the basic series is a series where a difference between the standard time period and the pseudo time period of the macro task is shortest, and the start time and the completion time of each of the tasks is estimated based on the standard time of each of the tasks in the macro task, and
(C) the pseudo execution data based on a result of estimation of (B) is generated.

10. The support system according to claim 9,
wherein in (B), the OT executor
(b1) identifies one or more start time groups, and one or more completion time groups,
where the start time group includes one or more given start times of the macro task that are sequential in a time series manner, and in the start time group, a difference between adjacent given start times is equal to or less than a certain value, and
the completion time group includes one or more given completion times of the macro task that are sequential in a time series manner, and in the completion time group, a difference between adjacent given completion times is equal to or less than a certain value,
(b2) identifies one or more start and completion groups,
where the start and completion group is a group that includes one or more start groups and one or more completion groups, and in the start and completion group, every given start time and every given completion time are closed in the start and completion group,
(b3) for each of the start and completion groups,
(b3-1) N basic series of time series are set,
for each of the start and completion groups, N is a natural number and a number that belongs to the start and completion group and is equal to or less than the number of non-standard series,
(b3-2) for each of the N basic series,
(b3-2-1) an entire m-th basic series that is the basic series is moved so as to overlay the completion time of the m-th basic series on the completion time of the non-standard series corresponding to the m-th basic series,
(b3-2-2) an entire upper level time group of the m-th basic series is moved so as to overlay the start time of the m-th basic series on the start time of the non-standard series corresponding to the m-th basic series,
a first basic series is a basic series having a latest start time among the N basic series, and
for each basic series, the upper level time group includes times including the start time of the basic series to an m-th time, and a first time is the start time.

11. The support system according to claim 2,
wherein the pseudo model includes an execution order of a plurality of macro tasks,
each of the macro tasks includes one or more tasks where the execution order is specified,
for each of the macro tasks, the OT executor
determines whether or not pseudo execution data generated for the macro task matches data about a macro task immediately before or immediately after the macro task concerned in an execution order, and
changes the pseudo execution data to data violating the scenario in an acceptable range, when a result of the determination is false.

12. The support system according to claim 1,
wherein the OT executor outputs a notification of an abnormality, when identifying the abnormality as a result of comparison between a result of execution of a normal on-site process and the pseudo execution data, or as a result of input of the pseudo execution data into a machine learning model learned based on data as a result of execution of the normal on-site process.

13. The support system according to claim 1,
wherein the OT executor
obtains pseudo execution data by executing the pseudo model in parallel with execution of the on-site process,
determines whether a condition defined as an abnormality is satisfied or not based on the pseudo execution data and on actual execution data obtained accompanied by execution of the on-site process, and
outputs the abnormality when a result of the determination is true.

14. The support system according to claim 2, further comprising
a scenario constructor configured to construct scenario data representing the scenario, based on data of data where a cause of target delay occurrence and an occurrence rate of the delay are designated, and data on knowledge of the OT-side process, upon input of the data,
wherein the OT executor executes the pseudo model, based on the scenario data constructed by the scenario constructor.

15. A support method for supporting system construction that requires data as a result of an OT-side process that is a process on an OT (Operation Technology) side, for an IT-side process that is a process on an IT (Information Technology) side, the method comprising:
executing a pseudo model that is a model simulating an on-site process that is at least part of the OT-side process,
the on-site process including one or more tasks that start and finish for each of one or more targets, and
executing the IT-side process, based on pseudo execution data that is data obtained by execution of the pseudo model.

16. A computer program causing a computer to:
execute a pseudo model that is a model simulating an on-site process that is at least part of an OT (Operation Technology) side process,
the OT-side process being a process on an OT side,
the on-site process including one or more tasks that start and finish for each of one or more targets, and
execute an IT-side process that is a process on an IT (Information Technology) side, based on pseudo execution data that is data obtained by executing the pseudo model.
